(19) United States
(12) Patent Application Publication
(10) Pub. No.: US 2025/0233103 A1
(43) Pub. Date: Jul. 17, 2025

(54) METHOD OF MANUFACTURING SEMICONDUCTOR DEVICE, HYBRID BONDING INSULATION FILM FORMING MATERIAL AND SEMICONDUCTOR DEVICE

(71) Applicant: HD MICROSYSTEMS, LTD., Tokyo (JP)

(72) Inventors: Satoshi YONEDA, Tokyo (JP); Kaori KOBAYASHI, Tokyo (JP); Kenya ADACHI, Tokyo (JP); Shingo TAHARA, Tokyo (JP); Daisaku MATSUKAWA, Tokyo (JP)

(21) Appl. No.: 18/854,011

(22) PCT Filed: Mar. 16, 2023
(86) PCT No.: PCT/JP2023/010464

§ 371 Date: Oct. 3, 2024

(30) Foreign Application Priority Data
Apr. 6, 2022 (JP) 2022-063656

(51) Int. Cl. H01L 23/00

(52) U.S. Cl. CPC H01L 24/80; H01L 24/08; H01L 2224/08145; H01L 2224/80379; H01L 2224/80895; H01L 2224/80896

(57) ABSTRACT

A method of manufacturing a semiconductor device includes preparing a first semiconductor substrate comprising a first semiconductor substrate body, a first electrode, and a first organic insulation film having a surface roughness Ra of 2.0 nm or less, in which the first electrode and the first organic insulation film are provided on one surface of the first semiconductor substrate body, preparing a second semiconductor substrate comprising a second semiconductor substrate body, a second electrode, and a second organic insulation film having a surface roughness Ra of 2.0 nm or less, in which the second electrode and the second organic insulation film are provided on one surface of the second semiconductor substrate body, performing lamination of the first organic insulation film and the second organic insulation film at 70° C. or less, and performing joining of the first electrode and the second electrode.

### TECHNICAL FIELD

The present disclosure relates to a method of manufacturing a semiconductor device, a hybrid bonding insulation film forming material and a semiconductor device.

### BACKGROUND ART

In recent years, three-dimensional packaging of semiconductor chips has been studied for increasing the degree of integration of LSIs (Large Scale Integrated Circuits). Non Patent Literature 1 discloses one example of three-dimensional packaging of semiconductor chips.

In the case of three-dimensional packaging of semiconductor chips performed by C2W (Chip-to-Wafer) joining, use of hybrid bonding techniques used for W2W (Wafer-to-Wafer) joining has been studied in order to perform fine joining of wiring between devices. C2W hybrid bonding has a risk of generation of misalignment caused by thermal expansion of base materials, chips, and the like, due to heating during bonding. Patent Literature 1 addresses such an issue and discloses one example of a technique that can lower the joining temperature with a cyclic olefin-based resin.

### CITATION LIST

### Patent Literature

Patent Literature 1: Japanese Patent Application Laid-Open (JP-A) No. 2019-204818

### Non Patent Literature

Non Patent Literature 1: F. C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

A method of C2W joining by a hybrid bonding technique with an organic insulation film is currently being studied and is not still in practical use. In a case in which the cyclic olefin-based resin described in Patent Literature 1 is used, the obtained organic insulation film is not sufficient in heat resistance, and exposure thereof to a high temperature during C2W joining may cause generation of joining failure at an interface or the like between a substrate and the organic insulation film. In this regard, the method of C2W joining by a hybrid bonding technique with an insulation film is demanded to be made at a low joining temperature.

The disclosure has been made in view of the above-mentioned conventional circumstances, and an object thereof is to provide a method of manufacturing a semiconductor device, in which the method allows for insulation film lamination in a low temperature condition, a hybrid bonding insulation film forming material used in the method of manufacturing a semiconductor device, and a semiconductor device in which joining failure of electrodes is decreased.

### Solution to Problem

Specific means for achieving the above-mentioned problems are as follows.

<1> A method of manufacturing a semiconductor device, the method comprising:
preparing a first semiconductor substrate comprising a first semiconductor substrate body, a first electrode, and a first organic insulation film having a surface roughness Ra of 2.0 nm or less, the first electrode and the first organic insulation film being provided on one surface of the first semiconductor substrate body;
preparing a second semiconductor substrate comprising a second semiconductor substrate body, a second electrode, and a second organic insulation film having a surface roughness Ra of 2.0 nm or less, the second electrode and the second organic insulation film being provided on one surface of the second semiconductor substrate body;
performing lamination of the first organic insulation film and the second organic insulation film at 70° C. or less; and
performing joining of the first electrode and the second electrode.
   <2> The method of manufacturing a semiconductor device according to <1>, wherein each of thermal expansion coefficients of the first organic insulation film and the second organic insulation film is 50 ppm/K or less.
   <3> The method of manufacturing a semiconductor device according to <1> or <2>, wherein each of the first organic insulation film and the second organic insulation film is a polyimide film, a polybenzoxazole film, a benzocyclobutene film, a polyamide imide film, an epoxy resin film, an acrylic resin film, or a methacrylic resin film.
   <4> The method of manufacturing a semiconductor device according to any one of <1> to <3>, wherein the first semiconductor substrate is a semiconductor wafer, and the second semiconductor substrate is a semiconductor wafer.
   <5> The method of manufacturing a semiconductor device according to any one of <1> to <3>, wherein the first semiconductor substrate is a semiconductor wafer, and the second semiconductor substrate is a semiconductor chip.
   <6> The method of manufacturing a semiconductor device according to any one of <1> to <3>, wherein the first semiconductor substrate is a semiconductor chip, and the second semiconductor substrate is a semiconductor chip.
   <7> The method of manufacturing a semiconductor device according to any one of <1> to <6>, wherein a total thickness of an organic insulation film formed by lamination of the first organic insulation film and the second organic insulation film, in the manufactured semiconductor device, is 0.1 μm or more.
   <8> The method of manufacturing a semiconductor device according to any one of <1> to <7>, wherein at least one of the one surface of the first semiconductor substrate or the one surface of the second semiconductor substrate is polished before lamination of the first organic insulation film and the second organic insulation film is carried out.
   <9> The method of manufacturing a semiconductor device according to <8>, wherein the polishing comprises chemical mechanical polishing.
   <10> The method of manufacturing a semiconductor device according to <9>, wherein the polishing further comprises mechanical polishing.
   <11> The method of manufacturing a semiconductor device according to any one of <1> to <10>, wherein a height of the first organic insulation film is equal to or higher than a height of the first electrode, and a height of the second organic insulation film is equal to or higher than a height of the second electrode.
   <12> The method of manufacturing a semiconductor device according to <11>, wherein the height of the first organic insulation film is higher than the height of the first electrode by 0.1 nm or more, and the height of the second organic insulation film is higher than the height of the second electrode by 0.1 nm or more.
   <13> A hybrid bonding insulation film forming material comprising a thermosetting polyamide and a solvent, wherein a thermal expansion coefficient of a cured product of the hybrid bonding insulation film forming material is 50 ppm/K or less.
   <14> The hybrid bonding insulation film forming material according to <13>, wherein the thermosetting polyamide comprises a polybenzoxazole precursor or a polyimide precursor.
   <15> The hybrid bonding insulation film forming material according to <13>, wherein the thermosetting polyamide comprises a polyimide precursor, and the hybrid bonding insulation film forming material further comprises a polyimide resin.
   <16> A semiconductor device comprising:
a first semiconductor substrate comprising a first semiconductor substrate body, a first organic insulation film, and a first electrode, the first organic insulation film and the first electrode being provided on one surface of the first semiconductor substrate body; and
a second semiconductor substrate comprising a second semiconductor substrate body, a second organic insulation film, and a second electrode, the second organic insulation film and the second electrode being provided on one surface of the second semiconductor substrate body, wherein:
the first organic insulation film and the second organic insulation film are joined, and the first electrode and the second electrode are joined, and
each of thermal expansion coefficients of the first organic insulation film and the second organic insulation film is 50 ppm/K or less.

### Advantageous Effects of Invention

The disclosure can provide a method of manufacturing a semiconductor device, in which the method allows for insulation film lamination in a low temperature condition, a hybrid bonding insulation film forming material used in the method of manufacturing a semiconductor device, and a semiconductor device in which joining failure of electrodes is decreased.

### BRIEF DESCRIPTION OF DRAWINGS

FIG. 1 is a cross-sectional view schematically illustrating one example of a semiconductor device manufactured by a method of manufacturing a semiconductor device according to one embodiment.

FIG. 2 sequentially illustrates a method of manufacturing the semiconductor device illustrated in FIG. 1.

FIG. 3 more specifically illustrates a joining method in the method of manufacturing the semiconductor device illustrated in FIG. 2.

FIG. 4 sequentially illustrates steps which are included in the method of manufacturing the semiconductor device illustrated in FIG. 1 and which are performed after the steps illustrated in FIG. 2.

FIG. 5 illustrates an example in which a method of manufacturing a semiconductor device according to one embodiment is applied to Chip-to-Wafer (C2W).

### DESCRIPTION OF EMBODIMENTS

The present disclosure are described below in detail. It is noted here, however, that the disclosure is not restricted to the below-described embodiments. In the below-described embodiments, the constituents thereof (including element steps and the like) are not indispensable unless otherwise specified. The same applies to the numerical values and ranges thereof, without restricting the disclosure.

In the disclosure, the term “step” encompasses not only steps discrete from other steps but also steps which cannot be clearly distinguished from other steps, as long as the intended purpose of the step is achieved.

In the disclosure, those numerical ranges that are expressed with “to” each denote a range that includes the numerical values stated before and after “to” as the minimum value and the maximum value, respectively.

In a set of numerical ranges that are stated stepwisely in the disclosure, the upper limit value or the lower limit value of a numerical range may be replaced with the upper limit value or the lower limit value of other numerical range. Further, in a numerical range stated in the disclosure, the upper limit or the lower limit of the numerical range may be replaced with a relevant value indicated in any of Examples.

In the disclosure, a component may include a plurality of different substances corresponding thereto. When there are plural kinds of substances that correspond to a component of a composition, the indicated content ratio or content amount of the component in the composition means, unless otherwise specified, the total content ratio or content amount of the plural kinds of substances existing in the composition.

In the disclosure, the term “layer” or “film” includes, when observing a region where a layer or film is present, a case in which the layer or the film is formed only on a part of the region in addition to a case in which the layer or the film is formed on the entirety of the region.

In the disclosure, “(meth)acrylic” means at least one of acrylic and methacrylic.

In the disclosure, a thickness of a layer or a film is a value obtained by measuring thicknesses at five points of a target layer or film and giving an arithmetic average value thereof.

The thickness of the layer or film can be measured using a micrometer or the like. In the disclosure, when the thickness of a layer or a film can be directly measured, the thickness is measured using a micrometer. On the other hand, when the thickness of one layer or the total thickness of a plurality of layers is measured, measurement may be performed by observing a cross section of a measurement target using an electron microscope.

In the disclosure, the thermal expansion coefficient means the proportion of expansion of the length of a measurement sample due to temperature rise, as represented per temperature. The thermal expansion coefficient refers to the value calculated by measurement of the amount of change in length of a measurement sample from 30° C. to 100° C. with a thermal mechanical analyzer or the like.

### <Method of Manufacturing Semiconductor Device and Semiconductor Device>

A method of manufacturing a semiconductor device of the disclosure includes preparing a first semiconductor substrate comprising a first semiconductor substrate body, a first electrode, and a first organic insulation film having a surface roughness Ra of 2.0 nm or less, in which the first electrode and the first organic insulation film are provided on one surface of the first semiconductor substrate body, preparing a second semiconductor substrate comprising a second semiconductor substrate body, a second electrode, and a second organic insulation film having a surface roughness Ra of 2.0 nm or less, in which the second electrode and the second organic insulation film are provided on one surface of the second semiconductor substrate body, performing lamination of the first organic insulation film and the second organic insulation film at 70° C. or less, and performing joining of the first electrode and the second electrode.

The method of manufacturing a semiconductor device of the disclosure allows for insulation film lamination in a low temperature condition. Although the reason for this is not clear, it is presumed that the surface roughness Ra of each of the first organic insulation film and the second organic insulation film is 2.0 nm or less to result in an increase in contact area between the insulation films and increases in intermolecular force and electrostatic force each acting between the insulation films.

In addition, a semiconductor device of the disclosure includes a first semiconductor substrate comprising a first semiconductor substrate body, a first organic insulation film, and a first electrode, the first organic insulation film and the first electrode being provided on one surface of the first semiconductor substrate body, and a second semiconductor substrate comprising a second semiconductor substrate body, a second organic insulation film, and a second electrode, the second organic insulation film and the second electrode being provided on one surface of the second semiconductor substrate body, wherein the first organic insulation film and the second organic insulation film are joined, and the first electrode and the second electrode are joined, and each of thermal expansion coefficients of the first organic insulation film and the second organic insulation film is 50 ppm/K or less.

The semiconductor device of the disclosure decreases electrode joining failure. Although the reason for this is not clear, it is presumed that, in a case in which the thermal expansion coefficient of each of the first organic insulation film and the second organic insulation film is 50 ppm/K or less, the thermal expansion coefficients of these insulation films are closer to the thermal expansion coefficients of members generally disposed around the insulation films, for example, the semiconductor substrates or the electrodes, and therefore the difference in thermal expansion coefficient between the insulation films and these members is smaller to hardly cause electrode joining failure due to thermal expansion.

Hereinafter, one embodiment of the method of manufacturing a semiconductor device of the disclosure and one embodiment of the semiconductor device of the disclosure are described in detail with reference to the drawings. In the following description, the same or corresponding portion is marked with the same symbol, and the overlapped description is omitted. A positional relationship of up/down, left/right, or the like is based on the positional relationship illustrated in the drawings, unless particularly noted. The dimensional relationship in the drawings is not limited to any ratio illustrated.

While a case in which both the first semiconductor substrate and the second semiconductor substrate are semiconductor chips is described in the following embodiment, the present embodiment is not limited thereto.

### (One Example of Semiconductor Device)

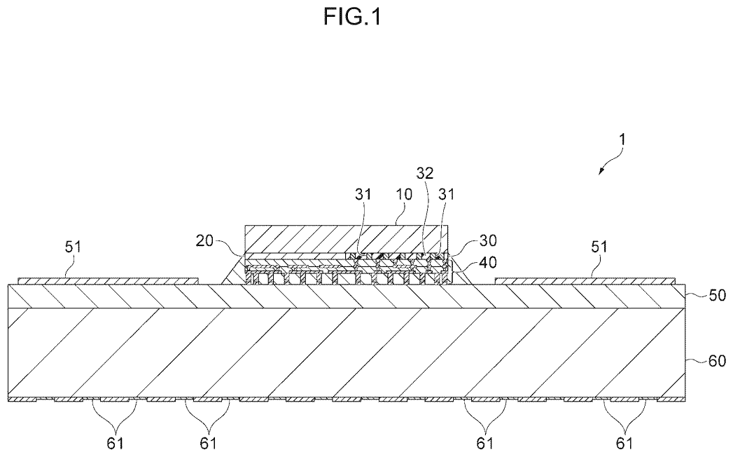

FIG. 1 is a cross-sectional view schematically illustrating one example of the semiconductor device of the disclosure. As illustrated in FIG. 1, a semiconductor device 1 is, for example, one example of semiconductor packages, and includes a first semiconductor chip 10 (first semiconductor substrate), a second semiconductor chip 20 (second semiconductor substrate), a pillar section 30, a rewiring layer 40, a substrate 50, and a circuit substrate 60.

The first semiconductor chip 10 is a semiconductor chip such as an LSI (Large Scale Integrated Circuit) chip or a CMOS (Complementary Metal Oxide Semiconductor) sensor, and has a three-dimensional packaging structure in which the second semiconductor chip 20 is packaged downward. The second semiconductor chip 20 is a semiconductor chip such as an LSI or a memory, and is a chip component smaller in area in planar view than the first semiconductor chip 10. The second semiconductor chip 20 is Chip-to-Chip (C2C) joined to the rear surface of the first semiconductor chip 10. The first semiconductor chip 10 and the second semiconductor chip 20 are such that respective terminal electrodes and their peripheral insulation films are firmly fine-joined by hybrid bonding described below in detail.

The pillar section 30 is a connecting section in which a plurality of pillars 31 formed by a metal such as copper (Cu) are sealed with a resin 32. The plurality of pillars 31 are a conductive member extending from the upper surface toward the lower surface of the pillar section 30. The plurality of pillars 31 may have, for example, a cylindrical shape having a diameter of from 3 μm to 20 μm (in one example, a diameter of 5 μm), and may be placed so that the distance between the centers of the pillars 31 is 15 μm or less. The plurality of pillars 31 provide flip chip connection between a terminal electrode at the downside of the first semiconductor chip 10 and a terminal electrode at the upside of the rewiring layer 40. The pillar section 30 is used, whereby a connection electrode can be formed in the semiconductor device 1 without any technique in which hole making is applied to a mold and solder connection is made, called TMV (Through mold via). The pillar section 30 has, for example, a thickness comparable with that of the second semiconductor chip 20, and is placed in a horizontal direction on the side of the second semiconductor chip 20. A plurality of solder balls may be placed instead of the pillar section 30, and a terminal electrode at the downside of the first semiconductor chip 10 and a terminal electrode at the upside of the rewiring layer 40 may be electrically connected by the solder balls.

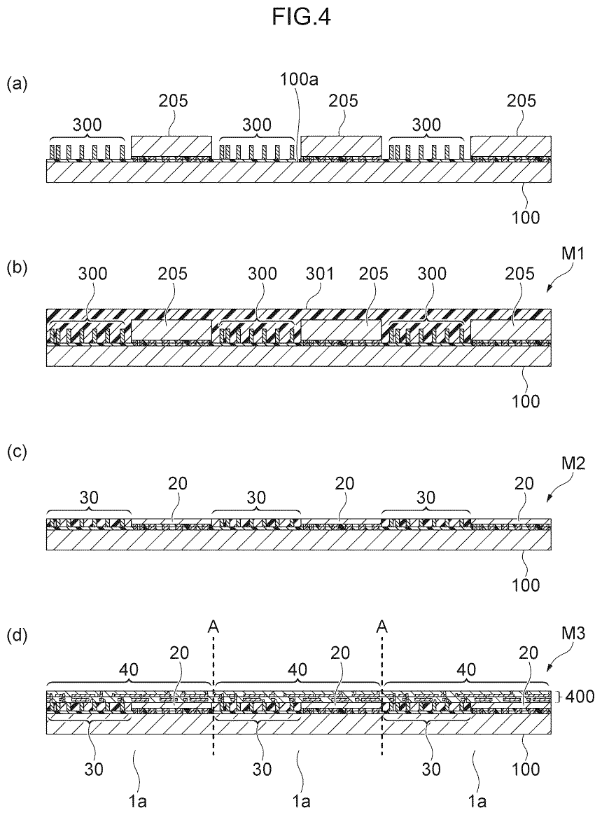

The rewiring layer 40 is a wiring layer having a function of terminal pitch conversion, which is a function of a package substrate, and is a layer in which a rewiring pattern is formed by polyimide and copper wiring or the like on an insulation film at the downside of second semiconductor chip 20 and on the lower surface of the pillar section 30. The rewiring layer 40 is formed in a state in which the first semiconductor chip 10, the second semiconductor chip 20, and the like are flipped vertically (see FIG. 4 (d)).

The rewiring layer 40 allows a terminal electrode on the lower surface of the second semiconductor chip 20 and a terminal electrode of the first semiconductor chip 10 with the pillar section 30 being interposed to be electrically connected to a terminal electrode of the substrate 50. The terminal pitch in the substrate 50 is wider than the terminal pitch in the pillars 31 and the terminal pitch in the second semiconductor chip 20. Various electronic components 51 may be mounted on the substrate 50. In a case in which the difference in terminal pitch between the rewiring layer 40 and the substrate 50 is large, the rewiring layer 40 and the substrate 50 may be electrically connected by an inorganic interposer or the like between the rewiring layer 40 and the substrate 50.

The circuit substrate 60 is a substrate, that includes therein a plurality of through electrodes that are electrically connected to the substrate 50 on which the first semiconductor chip 10 and the second semiconductor chip 20 are loaded, and to which the first semiconductor chip 10, the second semiconductor chip 20, the electronic component 51, and the like are connected. In the circuit substrate 60, the plurality of through electrodes allow respective terminal electrodes of the first semiconductor chip 10 and the second semiconductor chip 20 to be electrically connected to terminal electrodes 61 provided on the rear surface of the circuit substrate 60.

### (One Example of Method of Manufacturing Semiconductor Device)

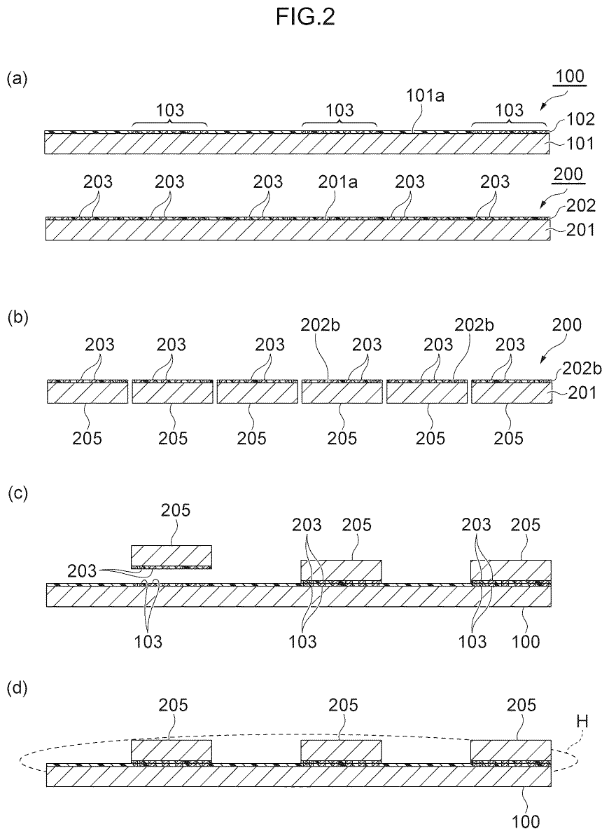

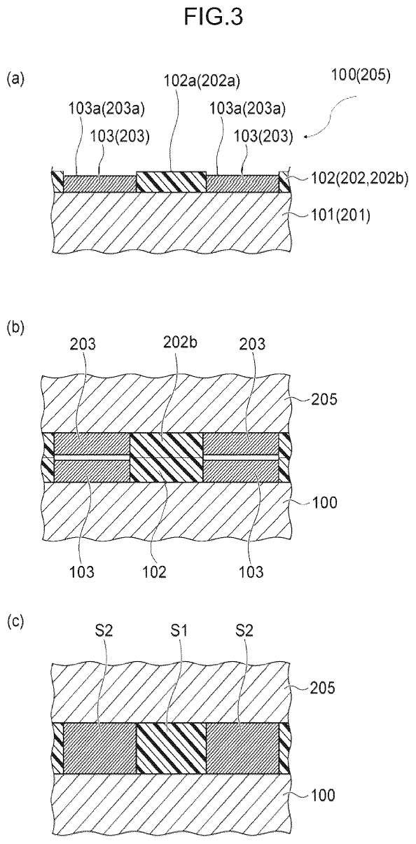

Next, one example of the method of manufacturing the semiconductor device 1 is described with reference to FIG. 2 to FIG. 4. FIG. 2 sequentially illustrates a method of manufacturing the semiconductor device illustrated in FIG. 1. FIG. 3 more specifically illustrates a joining method (hybrid bonding) in the method of manufacturing the semiconductor device illustrated in FIG. 2. FIG. 4 sequentially illustrates steps which are included in the method of manufacturing the semiconductor device illustrated in FIG. 1 and which are performed after the steps illustrated in FIG. 2.

The semiconductor device 1 can be produced through, for example, the following Step (a) to Step (n).

(a) A step of preparing a first silicon substrate 100 corresponding to the first semiconductor chip 10.

(b) A step of preparing a second silicon substrate 200 corresponding to the second semiconductor chip 20.

(c) A step of polishing the first silicon substrate 100.

(d) A step of polishing the second silicon substrate 200.

(e) A step of singulating the second silicon substrate 200, to obtain a plurality of semiconductor chips 205.

(f) A step of performing alignment of a terminal electrode 203 of each of the plurality of semiconductor chips 205 with respect to a terminal electrode 103 of the first silicon substrate 100.

(g) A step of mutually laminating an insulation film 102 of the first silicon substrate 100 and each insulation film portion 202b of the plurality of semiconductor chips 205 (see FIG. 3 (b)).

(h) A step of joining the terminal electrode 103 of the first silicon substrate 100 and a terminal electrode 203 of each of the plurality of semiconductor chips 205 (see FIG. 3 (c)).

(i) A step of forming a plurality of pillars 300 (corresponding to the pillars 31) on a connection surface of the first silicon substrate 100 and between the plurality of semiconductor chips 205.

(j) A step of molding a resin 301 on the connection surface of the first silicon substrate 100 so that the semiconductor chips 205 and the pillars 300 are covered, to obtain a semi-product M1.

(k) A step of grinding and thinning the resin 301 side of the semi-product M1 molded in Step (j), to obtain a semi-product M2.

(l) A step of forming a wiring layer 400 corresponding to the rewiring layer 40, on the semi-product M2 obtained by thinning in Step (k).

(m) A step of cutting a semi-product M3 in which the wiring layer 400 is formed in Step (l), so that each semiconductor device 1 is obtained, along with a cutting line A.

(n) A step of inverting a semiconductor device 1a individualized in Step (m) and disposing of the semiconductor device 1a on the substrate 50 and the circuit substrate 60 (see FIG. 1).

[Step (a) and Step (b)]

Step (a) is a step of preparing a first silicon substrate 100 (first semiconductor substrate) serving as a silicon substrate which corresponds to a plurality of the first semiconductor chips 10 and in which an integrated circuit including a semiconductor element, wiring for connection thereof, and the like is formed. In Step (a), as illustrated in FIG. 2 (a), a plurality of terminal electrodes 103 (first electrodes) made of copper, aluminum, or the like is provided at a predetermined gap on one surface 101a of a first silicon substrate body 101 (first semiconductor substrate body) made of silicon or the like, and an insulation film 102 (first organic insulation film) is provided on such a gap portion. The insulation film 102 may be provided on one surface 101a of the first silicon substrate body 101, and then the plurality of terminal electrodes 103 may be provided, or the plurality of terminal electrodes 103 may be provided on one surface 101a of the first silicon substrate body 101, and then the insulation film 102 may be provided. A predetermined gap for formation of the pillars 300 in a step described below is provided between the plurality of terminal electrodes 103, and another terminal electrode (not illustrated) connected to the pillars 300 is formed therebetween.

Step (b) is a step of preparing a second silicon substrate 200 (second semiconductor substrate) serving as a silicon substrate which corresponds to a plurality of the second semiconductor chips 20 and in which an integrated circuit including a semiconductor element, wiring for connection thereof, and the like is formed. In Step (b), as illustrated in FIG. 2 (a), not only a plurality of terminal electrodes 203 (a plurality of second electrodes) made of copper, aluminum, or the like is continuously provided on one surface 201a of a second silicon substrate body 201 (second semiconductor substrate body) made of silicon or the like, but also an insulation film 202 (second organic insulation film, organic insulation region) is provided on such one surface. The insulation film 202 may be provided on one surface 201a of the second silicon substrate body 201 and then the plurality of terminal electrodes 203 may be provided, or the plurality of terminal electrodes 203 may be provided on one surface 201a of the second silicon substrate body 201 and then the insulation film 202 may be provided. The surface roughness Ra of each of the insulation films 102 and 202 used in Step (a) and Step (b) is 2.0 nm or less, preferably 1.5 nm or less, still more preferably 1.0 nm or less.

Each of the insulation films 102 and 202 is preferably a polyimide film, a polybenzoxazole film, a benzocyclobutene film, a polyamide imide film, an epoxy resin film, an acrylic resin film, or a methacrylic resin film, and more preferably a polyimide film or a polybenzoxazole film, still more preferably a polyimide film, from the viewpoint of heat resistance.

The tensile elastic modulus at 25° C. of each of the insulation films 102 and 202 is preferably 7.0 GPa or less, more preferably 5.0 GPa or less, still more preferably 3.0 GPa or less, particularly preferably 2.5 GPa or less. The tensile elastic modulus at 25° C. of each of the insulation films 102 and 202 may be 2.0 MPa or more.

The thermal expansion coefficient of each of the insulation films 102 and 202 is preferably 50 ppm/K or less, more preferably 40 ppm/K or less, still more preferably 30 ppm/K or less. The thermal expansion coefficient of each of the insulation films 102 and 202 may be 3 ppm/K or more.

The thermal expansion coefficient of each of the insulation films 102 and 202 is 50 ppm/K or less, whereby expansion of the insulation films are not too large as compared with expansion of terminal electrodes in Step (h) described below, and the contact area between terminal electrodes after joining can be kept broad and the electrical resistance can be suppressed to a low value. A decrease in joining failure between terminal electrode is also achieved.

The thickness of each of the insulation films 102 and 202 is preferably from 0.1 μm to 50 μm, more preferably from 1 μm to 15 μm. Thus, not only uniformity of the thickness of each of the insulation films is kept, but also the treatment time in the subsequent polishing step can be shortened.

It is preferable from the viewpoint of facilitating operations performed in Step (c) and Step (d) and allowing for simplification of these Steps to satisfy at least one (preferably satisfy both) of the polishing rate of the insulation film 102, which is from 0.1 times to 5 times the polishing rate of the terminal electrode 103, and the polishing rate of the insulation film 202, which is from 0.1 times to 5 times the polishing rate of the terminal electrode 203.

As an example, in a case in which the terminal electrode 103 or 203 is made of copper and the polishing rate of copper is 500 nm/min, the polishing rate of the insulation film 102 or 202 is preferably 1500 nm/min or less (3 times or less the polishing rate of copper), more preferably 1000 nm/min or less (2 times or less the polishing rate of copper), still more preferably 500 nm/min or less (equal to or less than the polishing rate of copper).

Next, the method of producing such each insulation film is described. The insulation film is obtained by curing an insulation film forming material. Examples of the method of producing each of the above insulation films include a method including (a) a method including a step of applying and drying an insulation film forming material on a substrate, to form a resin film, and a step of heat-treating the resin film, and (B) a method including a step of forming a film of an insulation film forming material at a constant thickness on a film subjected to release treatment and then transferring such a resin film to a substrate by a lamination method, and a step of heat-treating the resin film formed on the substrate after transferring. The method (a) is preferred in terms of flatness. In a case in which the method (a) is used, the hybrid bonding insulation film forming material of the disclosure, described below, may be used.

The method of applying the insulation film forming material include a spin coating method, an ink-jet method, or a slit coating method.

The spin coating method may include, for example, spin coating with the insulation film forming material under conditions of a rate of revolution of from 300 rpm (revolutions per minute) to 3,500 rpm, preferably from 500 rpm to 1,500 rpm, a rate of acceleration of from 500 rpm/see to 15,000 rpm/see, and a time of revolution of from 30 seconds to 300 seconds.

The method may include a drying step after application of the insulation film forming material to a support, a film, or the like. The drying may be performed with a hot plate, an oven, or the like. The drying temperature is preferably from 75° C. to 130° C., and is more preferably from 90° C. to 120° C. from the viewpoint of an enhancement in flatness of the insulation films. The drying time is preferably from 30 seconds to 5 minutes.

The drying may be performed twice or more. Thus, a resin film can be obtained in which the above insulation film forming material is formed into a film.

The slit coating method may include, for example, slit coating with the insulation film forming material under conditions of a rate of chemical liquid discharge of from 10 μL/sec to 400 μL/sec, a height of a chemical discharge portion, of from 0.1 μm to 1.0 μm, a rate of a stage (or a rate of a chemical discharge portion), of from 1.0 mm/sec to 50.0 mm/sec, a rate of acceleration of a stage, of from 10 mm/sec to 1000 mm/sec, a degree of ultimate vacuum of drying under reduced pressure, of from 10 Pa to 100 Pa, a time of drying under reduced pressure of from 30 seconds to 600 seconds, a drying temperature of from 60° C. to 150° C., and a drying time of from 30 to 300 seconds.

The resin film formed may be heat-treated. The heating temperature is preferably from 150° C. to 450° C., more preferably from 150° C. to 350° C. The heating temperature is in the above range, whereby not only any damage to a substrate, a device, or the like is suppressed and energy saving of a process is realized, but also the insulation films can be suitably produced.

The heating time is preferably 5 hours or less, more preferably from 30 minutes to 3 hours. The time of the heat treatment is in the above range, whereby crosslinking reaction or cyclodehydration reaction can be allowed to sufficiently progress.

The atmosphere of the heat treatment may be air or may be an inert atmosphere of nitrogen or the like, and a nitrogen atmosphere is preferred from the viewpoint that oxidation of the resin film can be prevented.

Examples of the apparatus used for the heat treatment include a quartz tube furnace, a hot plate, a rapid thermal anneal, a vertical diffusion furnace, an infrared curing furnace, an electron beam curing furnace, or a microwave curing furnace.

In a case in which a negative-type photosensitive insulation film forming material or a positive-type photosensitive insulation film forming material is used, a method including, for example, a step of applying and drying the insulation film forming material onto a substrate, to form a resin film, a step of pattern-exposing the resin film and developing the resultant with a developer, to obtain a patterned resin film, and a step of heat-treating the patterned resin film may also be used when the insulation film 202 is provided on one surface 201a of the second silicon substrate body 201 and then the plurality of terminal electrodes 203 are provided. Thus, a patterned insulation film cured can be obtained.

The pattern-exposing is, for example, exposing to a predetermined pattern via a photomask.

Examples of the active light radiated include i-line, broadband ultraviolet light, visible light, or radioactive ray, and i-line is preferred. The exposure apparatus here used can be, for example, a parallel exposure machine, a projection exposure machine, a stepper, or a scanner exposure machine.

The patterned resin film, which is a resin film with a pattern formed, can be obtained by post-exposure development. In a case in which the insulation film forming material is a negative-type photosensitive insulation film forming material, an unexposed section is removed by a developer.

The organic solvent used as a negative-type developer can be singly a good solvent of a photosensitive resin film, or an appropriate mixture of a good solvent and a poor solvent.

Examples of the good solvent include N-methyl-2-pyrrolidone, N-acetyl-2-pyrrolidone, N,N-dimethylacetamide, N,N-dimethylformamide, dimethylsulfoxide, γ-butyrolactone, α-acetyl-γ-butyrolactone, 3-methoxy-N, N-dimethylpropanamide, cyclopentanone, cyclohexanone, or cycloheptanone.

Examples of the poor solvent include toluene, xylene, methanol, ethanol, isopropanol, propylene glycol monomethyl ether acetate, propylene glycol monomethyl ether, or water.

In a case in which the insulation film forming material is a positive-type photosensitive insulation film forming material, an exposed section is removed by a developer.

Examples of the solution used as a positive-type developer include a tetramethylammonium hydroxide (TMAH) solution or a sodium carbonate solution.

At least one of the negative-type developer or the positive-type developer may include a surfactant. The content of the surfactant is preferably from 0.01 parts by mass to 10 parts by mass, more preferably from 0.1 parts by mass to 5 parts by mass with respect to 100 parts by mass of the developer.

The developing time can be, for example, set to be double as compared with the time taken until the photosensitive resin film is immersed in the developer and the resin film is completely dissolved.

The developing time may be regulated depending on the thermosetting polyamide included in the insulation film forming material, and is, for example, preferably from 10 seconds to 15 minutes, more preferably from 10 seconds to 5 minutes, and is still more preferably from 20 seconds to 5 minutes from the viewpoint of productivity.

The patterned resin film after development may be washed with a rinse liquid.

The rinse liquid used may be singly distilled water, methanol, ethanol, isopropanol, toluene, xylene, propylene glycol monomethyl ether acetate, or propylene glycol monomethyl ether, or an appropriate mixture thereof, or may be a stepwise combination thereof.

A thermosetting non-conductive film (NCF: Non Conductive Film) or the like may be used as an organic material constituting the insulation films 102 and 202. The organic material may be an underfill material. The organic material constituting the insulation films 102 and 202 may also be a heat-resistant resin.

[Step (c) and Step (d)]

Step (c) is a step of polishing the first silicon substrate 100. In Step (c), as illustrated in FIG. 3 (a), one surface 101a as a surface of the first silicon substrate 100 is polished by a chemical mechanical polishing method (CMP method) so that a surface 102a of the insulation film 102 is located at an equal position comparable with or slightly higher (protruded) than the position of each surface 103a of the terminal electrode 103. Thus, the thickness of the insulation film 102 is equal to or greater than the thickness of the terminal electrode 103. In other words, the height of the insulation film 102 is equal to or higher than the height of the terminal electrode 103. In Step (c), for example, the first silicon substrate 100 can also be polished by a CMP method in a condition in which the terminal electrode 103 made of copper or the like is selectively polished deep. In Step (c), the substrate may be polished by a CMP method so that each surface 103a of the terminal electrode 103 is matched with the surface 102a of the insulation film 102. The polishing method is not limited to a CMP method, and back grind or the like may also be adopted. Mechanical polishing may also be performed by a polishing apparatus such as a surface planer, prior to polishing by a CMP method.

In a case in which the surface 102a of the insulation film 102 is located at an equal position comparable with or slightly higher than the position of each surface 103a of the terminal electrode 103, the difference in height between such each surface 103a and the surface 102a (namely, the difference between the thickness of the insulation film 102 and the thickness of the terminal electrode 103) is preferably 0 nm or more, more preferably 0.1 nm or more, still more preferably from 0.1 nm to 30 nm, particularly preferably from 2 nm to 15 nm.

The difference in height between the organic insulation film (surface 102a or the like) and the electrode (surface 103a or the like) in the disclosure refers to an arithmetic average in measurement at five points of a measurement object such as a wafer, with an atomic force microscope (AFM).

Step (d) is a step of polishing the second silicon substrate 200. In Step (d), as illustrated in FIG. 3 (a), one surface 201a as a surface of the second silicon substrate 200 is polished by a CMP method so that a surface 202a of the insulation film 202 is located at an equal position comparable with or slightly higher (protruded) than the position of each surface 203a of the terminal electrode 203. Thus, the thickness of the insulation film 202 is equal to or greater than the thickness of the terminal electrode 203. In other words, the height of the insulation film 202 is equal to or higher than the height of the terminal electrode 203. In Step (d), for example, the second silicon substrate 200 is polished by a CMP method in a condition in which the terminal electrode 203 made of copper or the like is selectively polished deep. In Step (d), the substrate may be polished by a CMP method so that each surface 203a of the terminal electrode 203 is matched with the surface 202a of the insulation film 202. The polishing method is not limited to a CMP method, and back grind or the like may also be adopted.

In a case in which the surface 202a of the insulation film 202 is located at an equal position comparable with or slightly higher than the position of each surface 203a of the terminal electrode 203, the difference in height between such each surface 203a and the surface 202a (namely, the difference between the thickness of the insulation film 202 and the thickness of the terminal electrode 203) is preferably 0 nm or more, more preferably 0.1 nm or more, still more preferably from 0.1 nm to 30 nm, particularly preferably from 2 nm to 15 nm.

In Step (c) and Step (d), polishing may be made so that the thickness of the insulation film 102 is equal to the thickness of the insulation film 202, or, for example, polishing may be made so that the thickness of the insulation film 202 is greater than the thickness of the insulation film 102. In this regard, polishing may be made so that the thickness of the insulation film 202 is less than the thickness of the insulation film 102. In a case in which the thickness of the insulation film 202 is greater than the thickness of the insulation film 102, most of foreign objects attached to a joining interface can be incorporated by the insulation film 202 in singulation of the second silicon substrate 200 or in chip packaging, and joining failure can be much further decreased. In this regard, in a case in which the thickness of the insulation film 202 is less than the thickness of the insulation film 102, a decrease in height of semiconductor chips 205 packaged, namely, a semiconductor device 1 can be achieved.

At least one of Step (c) or Step (d) may be carried out, and both of Step (c) and Step (d) are preferably carried out.

[Step (e)]

Step (e) is a step of singulating the second silicon substrate 200, to obtain a plurality of semiconductor chips 205. In Step (e), as illustrated in FIG. 2 (b), the second silicon substrate 200 is singulated to a plurality of semiconductor chips 205 by a cutting procedure such as dicing. The second silicon substrate 200, when diced, may be singulated after covering of the insulation film 202 with a protection material or the like. Step (e) allows the insulation film 202 of the second silicon substrate 200 to be divided into an insulation film portion 202b corresponding to each of the semiconductor chips 205. Examples of the dicing method involving singulating the second silicon substrate 200 include plasma dicing, stealth dicing, or laser dicing. For example, a thin film such as an organic film removable by water, TMAH, or the like, or a carbon film removable by plasma or the like, may be provided as a surface protection material of the second silicon substrate 200 in dicing.

While the plurality of semiconductor chips 205 are obtained by preparing and then singulating the second silicon substrate 200 having a large area in this embodiment, the method of preparing the semiconductor chips 205 is not limited thereto.

[Step (f)]

Step (f) is a step of performing alignment of a terminal electrode 203 of each of the plurality of semiconductor chips 205 with respect to a terminal electrode 103 of the first silicon substrate 100. In Step (f), as illustrated in FIG. 2 (c), each of the semiconductor chips 205 is aligned so that the terminal electrode 203 of each of the plurality of semiconductor chips 205 face each corresponding one of the plurality of terminal electrodes 103 of the first silicon substrate 100. An alignment mark or the like for such alignment may be provided on the first silicon substrate 100.

[Step (g)]

Step (g) is a step of mutually laminating an insulation film 102 of the first silicon substrate 100 and each insulation film portion 202b of the plurality of semiconductor chips 205. In Step (g), an organic substance, a metal oxide, or the like attached to a surface of each of the semiconductor chips 205 is removed, thereafter each of the semiconductor chips 205 is aligned with respect to the first silicon substrate 100 as illustrated in FIG. 2 (c), and thereafter, each insulation film portion 202b of the plurality of semiconductor chips 205 is laminated at 70° C. or less, to the insulation film 102 of the first silicon substrate 100, as hybrid bonding (see FIG. 3 (b)). The “lamination at 70° C. or less” of the insulation film in the disclosure refers to lamination of the insulation film in a state in which the temperature of the insulation film is 70° C. or less. The lamination temperature is more preferably 60° C. or less, still more preferably 50° C. or less.

The pressure in lamination of the insulation film is preferably 7 MPa or less, and 0.1 MPa or more, more preferably 5 MPa or less, and 0.3 MPa or more, still more preferably 2 MPa or less, and 0.5 MPa or more. This pressure range can not only prevent a semiconductor element to be laminated, from being broken, but also allow the yield of the substrate laminated to be kept at a certain or higher level.

The time taken for a process in lamination of the insulation film is preferably 30 seconds or less, and 0.5 seconds or more, more preferably 20 seconds or less, and 1 second or more. Such a process time can allow the yield of the substrate laminated to be kept at a certain or higher level without any reduction in production efficiency.

The terminal electrode 103 of the first silicon substrate 100 and the terminal electrode 203 of each of the semiconductor chips 205 are separate from each other and are not connected at the stage of this attachment (it is noted that alignment is made within an apparatus error included).

[Step (h)]

Step (h) is a step of joining the terminal electrode 103 of the first silicon substrate 100 and a terminal electrode 203 of each of the plurality of semiconductor chips 205. In Step (h), as illustrated in FIG. 2 (d), the terminal electrode 103 of the first silicon substrate 100 and each terminal electrode 203 of the plurality of semiconductor chips 205 are joined as hybrid bonding by application of heat H and, if necessary, pressure once lamination in Step (g) is completed (see FIG. 3 (c)). In a case in which the terminal electrodes 103 and 203 are constituted from copper, the annealing temperature in Step (g) is preferably from 150° C. to 400° C., more preferably from 200° C. to 300° C. Such joining treatment provides an electrode joining portion S2 in which the terminal electrode 103 and the corresponding terminal electrode 203 are joined, and allows the terminal electrode 103 and this terminal electrode 203 to be mechanically and electrically firmly joined. The insulation film 102 and the insulation film portion 202b laminated are joined to provide an insulation joining portion S1.

The heat H is applied to expand the insulation film 102, the insulation film portion 202b, the terminal electrode 103, and the terminal electrode 203. The first silicon substrate 100 may be polished in Step (c) so that the height of the insulation film 102 is equal to or higher than the height of the terminal electrode 103 by thermal expansion with heating, and the second silicon substrate 200 may be polished in Step (d) so that the height of the insulation film portion 202b is equal to or higher than the height of the terminal electrode 203 by thermal expansion with heating. In a case in which the first silicon substrate 100 is polished in Step (c), the amount of polishing may be adjusted in consideration of the thermal expansion coefficients of the insulation film 102 and the terminal electrode 103. In a case in which the second silicon substrate 200 is polished in Step (d), the amount of polishing may be adjusted in consideration of the thermal expansion coefficients of the insulation film 202 and the terminal electrode 203.

The thickness of an organic insulation film as the insulation joining portion in which the insulation film 102 and the insulation film portion 202b are joined (the total thickness of an organic insulation film formed by lamination of the first organic insulation film and the second organic insulation film) is not particularly limited, may be, for example, 0.1 μm or more, and may be from 1 μm to 20 μm and is preferably from 1 μm to 5 μm from the viewpoint of suppression of the influence by foreign objects and from the viewpoint of device design.

From the foregoing, the plurality of semiconductor chips 205 are electrically and mechanically disposed on the first silicon substrate 100 at a predetermined position at a high accuracy. A semi-product illustrated in FIG. 2 (d) may be subjected to a product reliability test (connection test or the like), and only any non-defective product may be used in the subsequent steps. Subsequently, one example method of producing a semiconductor device with such a semi-product is described with reference to FIG. 4.

[Step (i)]

Step (i) is a step of forming a plurality of pillars 300 on a connection surface 100a of the first silicon substrate 100 and between the plurality of semiconductor chips 205. In Step (i), as illustrated in FIG. 4 (a), for example, many pillars 300 made of copper are formed between the plurality of semiconductor chips 205. Such a pillar 300 can be formed by copper plating, a conductive paste, a copper pin, or the like. Such a pillar 300 is formed so that one end thereof is connected to a terminal electrode not connected to the terminal electrode 203 of each of the semiconductor chips 205, among terminal electrodes of the first silicon substrate 100, and other end thereof extends upward. Such a pillar 300 has, for example, a diameter of from 10 μm to 100 μm, and a height of from 10 μm to 1000 μm. For example, 1 to 10000 of such pillars 300 may be provided between the semiconductor chips 205 paired.

[Step (j)]

Step (j) is a step of molding a resin 301 on the connection surface 100a of the first silicon substrate 100 so that the plurality of semiconductor chips 205 and the plurality of pillars 300 are covered. In Step (j), as illustrated in FIG. 4 (b), an epoxy resin or the like is molded to entirely cover the plurality of semiconductor chips 205 and the plurality of pillars 300. Examples of the molding method include compression molding, transfer molding, or a method of laminating a film-shaped epoxy film. This resin molding allows the resin 301 to be packed between the plurality of pillars 300, and between the pillars 300 and the semiconductor chips 205.

Thus, a semi-product M1 with a resin packed is formed. After molding of an epoxy resin or the like, curing treatment may be performed. In a case in which Step (i) and Step (j) are performed almost at the same time, namely, in a case in which the pillars 300 are also formed at the timing of resin molding, the pillars may be formed with imprint which is fine transfer, and a conductive paste or electrolytic plating.

[Step (k)]

Step (k) is a grinding and thinning the resin 301 of the semi-product M1 including the resin 301 molded in Step (j), the plurality of pillars 300 and the plurality of semiconductor chips 205, to obtain a semi-product M2. In Step (k), as illustrated in FIG. 4 (c), the top of the semi-product M1 is polished by a grinder or the like, thereby thinning the first silicon substrate 100 or the like in which resin molding is made, and providing a semi-product M2. The polishing in Step (k) leads to thinning of the thicknesses of the semiconductor chips 205, the pillars 300, and the resin 301 to, for example, about several tens of micrometers, and allows the semiconductor chips 205 to be shaped so as to correspond to the second semiconductor chips 20, and allows the pillars 300 and the resin 301 to be shaped so as to correspond to the pillar section 30.

[Step (l)]

Step (l) is a step of forming a wiring layer 400 corresponding to the rewiring layer 40, on the semi-product M2 obtained by thinning in Step (k). In Step (l), as illustrated in FIG. 4 (d), a rewiring pattern is formed by polyimide, copper wiring, or the like on the second semiconductor chips 20 and the pillar section 30 on the semi-product M2 ground. Thus, a semi-product M3 having a wiring structure in which the terminal pitch between the second semiconductor chips 20 and the pillar section 30 is extended is formed.

[Step (m) and Step (n)]

Step (m) is a step of cutting the semi-product M3 in which the wiring layer 400 is formed in Step (l), so that each semiconductor device 1 is obtained, along with a cutting line A. In Step (m), as illustrated in FIG. 4 (d), a semiconductor device substrate is cut by dicing or the like along with a cutting line A so as to serve as each semiconductor device 1. Thereafter, in Step (n), a semiconductor device 1a individualized in Step (m) is inverted and disposed on the substrate 50 and the circuit substrate 60, to obtain a plurality of the semiconductor devices 1 illustrated in FIG. 1.

One embodiment of the method of manufacturing a semiconductor device of the disclosure is described above in detail, but the disclosure is not limited to the above embodiment. For example, while Step (j) of molding the resin 301 and Step (k) of grinding and thinning the resin 301 or the like are sequentially performed after Step (i) of forming the pillars 300 in steps illustrated in FIG. 4 in the above embodiment, Step (j) of molding the resin 301 on a connection surface of the first silicon substrate 100 may be first performed, Step (k) of grinding and thinning the resin 301 to a predetermined thickness may be subsequently performed, and Step (i) of forming the pillars 300 may be then performed. In this case, an operation of polishing the pillars 300 can be decreased, and a portion to be polished, among the pillars 300, is unnecessary and thus the material cost can be reduced.

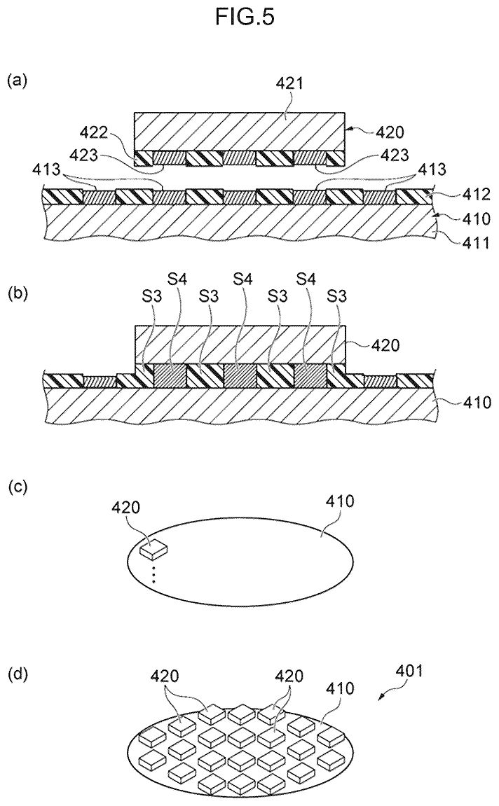

While the joining example with C2C is described in the above embodiment, the disclosure may also be applied to joining with Chip-to-Wafer (C2W) illustrated in FIG. 5. C2W involves not only preparing a semiconductor wafer 410 (first semiconductor substrate) which has a substrate body 411 (first semiconductor substrate body), and an insulation film 412 (first insulation film) and a plurality of terminal electrodes 413 (first electrodes) provided on one surface of the substrate body 411, but also preparing a semiconductor substrate which has a substrate body 421, and an insulation film portion 422 (second insulation film) and a plurality of terminal electrodes 423 (second electrodes) provided on one surface of the substrate body 421, and which is to be singulated to a plurality of semiconductor chips 420 (second semiconductor substrate). One surface of the semiconductor wafer 410 and one surface of the semiconductor substrate to be singulated to the semiconductor chips 420 are polished by a CMP method or the like in the same manner as in Step (c) and Step (d) described above. Thereafter, the semiconductor substrate to be singulated is subjected to the same singulation treatment as in Step (e), to obtain the plurality of semiconductor chips 420.

Subsequently, as illustrated in FIG. 5 (a), the terminal electrodes 423 of the semiconductor chips 420 are aligned with the terminal electrodes 413 of the semiconductor wafer 410 (Step (f)). Not only the insulation film 412 of the semiconductor wafer 410 and the insulation film portion 422 of the semiconductor chips 420 are mutually laminated (Step (g)), but also the terminal electrodes 413 of the semiconductor wafer 410 and the terminal electrodes 423 of the semiconductor chips 420 are joined (Step (h)), and thus a semi-product illustrated in FIG. 5 (b) is obtained. Thus, an insulation joining portion S3 in which the insulation film 412 and the insulation film portion 422 are joined is obtained, and the semiconductor chips 420 are mechanically firmly attached to the semiconductor wafer 410 at a high accuracy. An electrode joining portion S4 in which the terminal electrodes 413 and the corresponding terminal electrodes 423 are joined is also obtained, and the terminal electrodes 413 and the terminal electrodes 423 are mechanically and electrically firmly joined.

Thereafter, as illustrated in FIGS. 5 (c) and (d), the semiconductor chips 420 are joined to the semiconductor wafer 410 as a semiconductor wafer by the same method, whereby a semiconductor device 401 is obtained. The semiconductor chips 420 may be joined to the semiconductor wafer 410, one by one, by hybrid bonding, or may be collectively joined to the semiconductor wafer 410, by hybrid bonding.

The method of manufacturing a semiconductor device of the disclosure can also be applied to a manufacturing method according to W2W in which the first semiconductor substrate is a semiconductor wafer and the second semiconductor substrate is a semiconductor wafer.

An inorganic material may be included in a part of the insulation film 102 of the semiconductor substrate 100, the insulation film 202 of the semiconductor chips 205, or the like in the method of manufacturing a semiconductor device, as long as the effects of the disclosure are exerted.

### <Hybrid Bonding Insulation Film Forming Material>

The hybrid bonding insulation film forming material (hereinafter, the hybrid bonding insulation film forming material may be simply referred to as “insulation film forming material”.) of the disclosure includes a thermosetting polyamide and a solvent, and a cured product of the hybrid bonding insulation film forming material has a thermal expansion coefficient of 50 ppm/K or less. The thermal expansion coefficient of the cured product is preferably 40 ppm/K or less, more preferably 30 ppm/K or less. The thermal expansion coefficient of the cured product may be 3 ppm/K or more.

The first organic insulation film and the second organic insulation film in the method of manufacturing a semiconductor device of the disclosure may be each a cured product of the insulation film forming material of the disclosure.

The insulation film forming material of the disclosure may include a thermosetting or photo-curable resin such as an epoxy resin, an acrylic resin, or a methacrylic resin, instead of the thermosetting polyamide.

The insulation film forming material of the disclosure may include a thermosetting or photo-curable resin such as an epoxy resin, an acrylic resin, or a methacrylic resin, in combination with the thermosetting polyamide. In this case, the content rate of the thermosetting polyamide in the entire resin included in the insulation film forming material of the disclosure is preferably from 50% by mass to less than 100% by mass, more preferably from 70% by mass to less than 100% by mass, still more preferably from 90% by mass to less than 100% by mass, particularly preferably from 95% by mass to less than 100% by mass.

Examples of the thermosetting polyamide used in the disclosure include a polybenzoxazole precursor or a polyimide precursor (polyamide acid or the like).

In particular, a polyimide precursor is preferred from the viewpoint of heat resistance, adhesiveness to an electrode, or the like.

Hereinafter, the detail of the insulation film forming material of the disclosure is described mainly with a case in which a polyimide precursor is included as the thermosetting polyamide, as an example.

A polyimide precursor (A) is preferably at least one resin selected from the group consisting of polyamide acid, polyamide acid ester, a polyamide acid salt, and polyamide acid amide. The polyamide acid ester and the polyamide acid amide are each a compound in which hydrogen atoms of at least some carboxy groups in polyamide acid are substituted with monovalent organic groups, and the polyamide acid salt is a compound in which at least some carboxy groups in polyamide acid are taken with a basic compound having a pH of 7 or more to form a salt structure.

The polyimide precursor (A) preferably includes a compound having a structure unit represented by the following Formula (1). Thus, a semiconductor device including an insulation film exhibiting high reliability tends to be obtained.

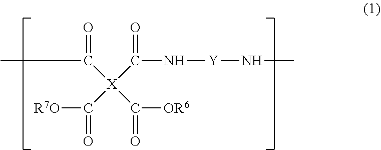

In Formula (1), X represents a tetravalent organic group, and Y represents a divalent organic group. Each of R⁶ and R⁷ independently represents a hydrogen atom or a monovalent organic group, and at least one of R⁶ or R⁷ may have a polymerizable unsaturated bond.

The polyimide precursor may have a plurality of the structure units represented by Formula (1), and Xs, Ys, R⁶s and R⁷s in the plurality of the structure units may be each the same or different.

A combination of R⁶ and R⁷ is not particularly limited as long as each thereof independently represents a hydrogen atom or a monovalent organic group. For example, at least one of R⁶ or R⁷ may be a hydrogen atom and the balance thereof may be a monovalent organic group described later, and the same monovalent organic group may be adopted or different monovalent organic groups from each other may be adopted. In a case in which the polyimide precursor has a plurality of the structure units represented by Formula (1) as described above, a combination of R⁶ and R⁷ may be the same or different between the structure units.

In Formula (1), the number of carbon atoms in the tetravalent organic group represented by X is preferably from 4 to 25, more preferably from 5 to 13, still more preferably from 6 to 12.

The tetravalent organic group represented by X may contain an aromatic ring, or may contain an alicyclic ring. Examples of the aromatic ring include an aromatic hydrocarbon group (for example, the number of carbon atoms constituting the aromatic ring is from 6 to 20), or an aromatic heterocyclic group (for example, the number of atoms constituting the heterocycle is from 5 to 20). Examples of the alicyclic ring include a cycloalkane structure having from 3 to 8 carbon atoms, or a spiro ring structure having from 5 to 25 carbon atoms. The tetravalent organic group represented by X is preferably an aromatic hydrocarbon group from the viewpoint of heat resistance. Examples of the aromatic hydrocarbon group include a benzene ring, a naphthalene ring, a phenanthrene ring, or the like.

In a case in which the tetravalent organic group represented by X contains an aromatic ring, each aromatic ring may have a substituent, or may be unsubstituted. Examples of the substituent of such each aromatic ring include an alkyl group, a fluorine atom, an alkyl halide group, a hydroxy group, or an amino group.

In a case in which the tetravalent organic group represented by X contains a benzene ring, the tetravalent organic group represented by X preferably contains from 1 to 4 benzene rings, more preferably from 1 to 3 benzene rings, still more preferably contains 1 or 2 benzene rings.

In a case in which the tetravalent organic group represented by X contains two or more benzene rings, such benzene rings may be linked by a single bond, or may be bound by a linking group such an alkylene group, an alkylene halide group, a carbonyl group, a sulfonyl group, an ether bond (—O—), a sulfide bond (—S—), a silylene bond (—Si (R^{A})₂—; each of two R^{A}s independently represents a hydrogen atom or an alkyl group or phenyl group.), or a siloxane bond (—O—(Si (R^{B})₂—O—)ₙ; each of two RBs independently represents a hydrogen atom, an alkyl group, or a phenyl group, and n represents an integer of 1 or 2 or more.), a composite linking group in which at least two of these linking groups are combined, or the like. Alternatively, two benzene rings may be bound by at least one of a single bond or a linking group at two sites, to form a five-membered ring or a six-membered ring containing a linking group between two benzene rings.

In Formula (1), a —COOR⁶ group and a —CONH— group are preferably located mutually at the ortho-position, and a —COOR⁷ group and a —CO— group are preferably located mutually at the ortho-position.

Specific examples of the tetravalent organic group represented by X include respective groups represented by the following Formula (A) to Formula (F). In particular, a group represented by the following Formula (E) is preferred, a group represented by the following Formula (E), in which C contains an ether bond, is more preferred, and an ether bond is still more preferred, from the viewpoint that an insulation film is obtained which is excellent in flexibility and more suppressed in void generation at a joining interface.

The disclosure is not limited to the following specific examples.

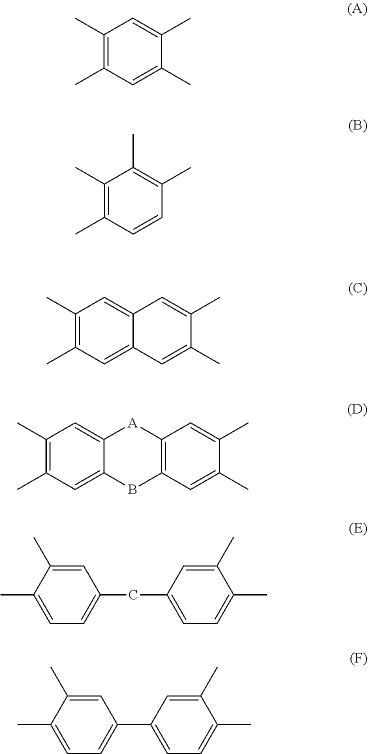

In Formula (D), each of A and B is independently a single bond, or a divalent group not conjugated with any benzene ring. It is noted that both A and B are not single bonds at the same time. Examples of the divalent group not conjugated with any benzene ring include a methylene group, a methylene halide group, a methylmethylene halide group, a carbonyl group, a sulfonyl group, an ether bond (—O—), a sulfide bond (—S—), or a silylene bond (—Si (R⁴)₂—; each of two R^{A}s independently represents a hydrogen atom or an alkyl group or phenyl group.). In particular, each of A and B is independently preferably a methylene group, a bis(trifluoromethyl)methylene group, a difluoromethylene group, an ether bond, a sulfide bond, or the like, more preferably an ether bond.

In Formula (E), C represents an alkylene group, an alkylene halide group, a carbonyl group, a sulfonyl group, an ether bond (—O—), a sulfide bond (—S—), a phenylene group, an ester bond (—O—C(═O)—), a silylene bond (—Si (R^{A})₂—; each of two R^{A}s independently represents a hydrogen atom or an alkyl group or phenyl group.), a siloxane bond (—O—(Si (R^{B})₂—O—)ₙ; each of two R^{B}s independently represents a hydrogen atom, an alkyl group, or a phenyl group, and n represents an integer of 1 or 2 or more.), or a divalent group in which at least two thereof are combined. C preferably contains an ether bond, and is preferably an ether bond.

C may be a structure represented by the following Formula (C1).

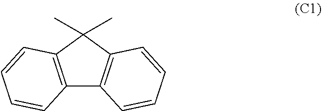

The alkylene group represented by C in Formula (E) is preferably an alkylene group having from 1 to 10 carbon atoms, more preferably an alkylene group having from 1 to 5 carbon atoms, still more preferably an alkylene group having 1 or 2 carbon atoms.

Specific examples of the alkylene group represented by C in Formula (E) include a linear alkylene group such as a methylene group, an ethylene group, a trimethylene group, a tetramethylene group, a pentamethylene group, or a hexamethylene group; or a branched alkylene group such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethyltrimethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, or a 1,4-dimethyltetramethylene group. In particular, a methylene group is preferred.

The alkylene halide group represented by C in Formula (E) is preferably an alkylene halide group having from 1 to 10 carbon atoms, more preferably an alkylene halide group having from 1 to 5 carbon atoms, still more preferably an alkylene halide group having from 1 to 3 carbon atoms.

Specific examples of the alkylene halide group represented by C in Formula (E) include the above alkylene group represented by C in Formula (E), in which at least one hydrogen atom contained is substituted with a halogen atom such as a fluorine atom or a chlorine atom. In particular, a fluoromethylene group, a difluoromethylene group, a hexafluorodimethylmethylene group, or the like is preferred.

The alkyl group represented by R^{A} or R^{B} contained in the silylene bond or siloxane bond is preferably an alkyl group having from 1 to 5 carbon atoms, more preferably an alkyl group having from 1 to 3 carbon atoms, still more preferably an alkyl group having 1 or 2 carbon atoms. Specific examples of the alkyl group represented by R^{A} or R^{B} include a methyl group, an ethyl group, an n-propyl group, an isopropyl group, an n-butyl group, an isobutyl group, an s-butyl group, or a t-butyl group.

Specific examples of the tetravalent organic group represented by X may be respective groups represented by the following Formula (J) to Formula (O).

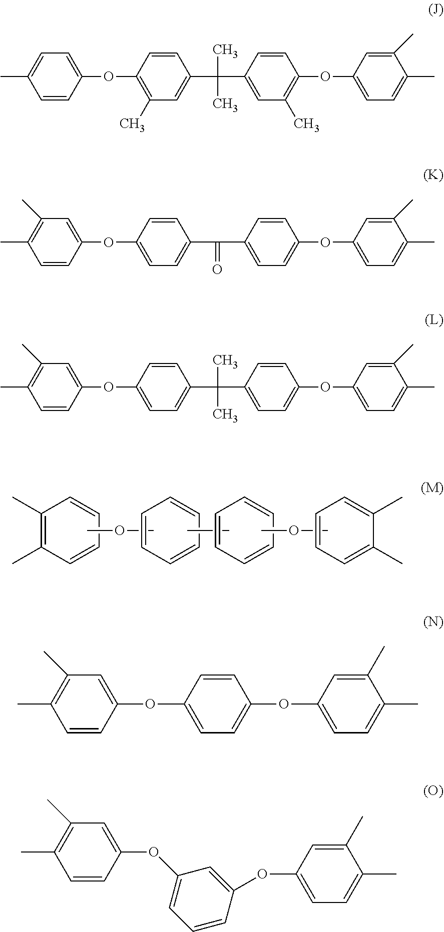

The tetravalent organic group represented by X may contain an alicyclic ring from the viewpoint of adjustment of the thermal expansion coefficient of a cured product to be formed. In a case in which the tetravalent organic group represented by X contains an alicyclic ring, examples include a ring structure containing no unsaturated bond, such as a cyclopropane ring, a cyclobutane ring, a cyclopentane ring, a cyclohexane ring, a cycloheptane ring, a cyclooctane ring, a decahydronaphthalene ring, a norbornane ring, an adamantane ring, or a bicyclo[2.2.2] octane ring, or a ring structure containing an unsaturated bond, such as a cyclohexene ring. Examples also include a spiro ring structure containing such a ring structure. The alicyclic ring may have a substituent such as an oxo group (═O), an alkyl group, a fluorine atom, an alkyl halide group, a hydroxy group, or an amino group, or may be unsubstituted.

In a case in which the tetravalent organic group represented by X has a spiro ring structure, specific examples include the following Formula (P).

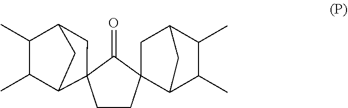

In Formula (1), the number of carbon atoms in the divalent organic group represented by Y is preferably from 4 to 25, more preferably from 6 to 20, still more preferably from 12 to 18.

The backbone of the divalent organic group represented by Y may be the same as the backbone of the tetravalent organic group represented by X, and a preferred backbone of the divalent organic group represented by Y may be the same as a preferred backbone of the tetravalent organic group represented by X. The backbone of the divalent organic group represented by Y may be a structure substituted with an atom (for example, hydrogen atom) or a functional group (for example, alkyl group) at two binding sites in the tetravalent organic group represented by X.

The divalent organic group represented by Y may be a divalent aliphatic group, or may be a divalent aromatic group. The divalent organic group represented by Y is preferably a divalent aromatic group from the viewpoint of heat resistance. Examples of the divalent aromatic group include a divalent aromatic hydrocarbon group (for example, the number of carbon atoms constituting the aromatic ring is from 6 to 20), or a divalent aromatic heterocyclic group (for example, the number of atoms constituting the heterocycle is from 5 to 20), and a divalent aromatic hydrocarbon group is preferred.

Specific examples of the divalent aromatic group represented by Y can include respective groups represented by the following Formula (G) to the following Formula (H). In particular, a group represented by the following Formula (H) is preferred, a group represented by the following Formula (H), in which D contains a single bond or an ether bond, is more preferred, a single bond or an ether bond is still more preferred, from the viewpoint that an insulation film is obtained which is excellent in flexibility and more suppressed in generation of voids at a joining interface.

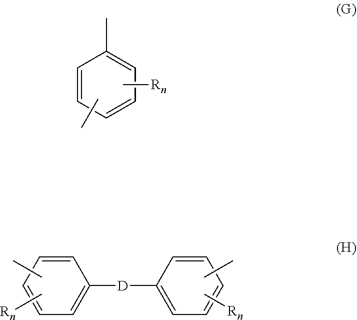

In Formula (G) to Formula (H), each R independently represents an alkyl group, an alkoxy group, a hydroxyl group, an alkyl halide group, a phenyl group, or a halogen atom, and each n independently represents an integer of from 0 to 4.

In Formula (H), D represents a single bond, an alkylene group, an alkylene halide group, a carbonyl group, a sulfonyl group, an ether bond (—O—), a sulfide bond (—S—), a phenylene group, an ester bond (—O—C(═O)—), a silylene bond (—Si (R^{A})₂—; each of two R^{A}s independently represents a hydrogen atom or an alkyl group or phenyl group.), a siloxane bond (—O—(Si (R^{B})₂—O—)ₙ; each of two R^{B}s independently represents a hydrogen atom, an alkyl group, or a phenyl group, and n represents an integer of 1 or 2 or more.), or a divalent group in which at least two thereof are combined. D may be the structure represented by Formula (C1). A specific example of D in Formula (H) is a single bond, or is the same as a specific example of C in Formula (E).

Each D in Formula (H) is independently preferably a single bond, an ether bond, a group containing an ether bond and a phenylene group, a group containing an ether bond, a phenylene group, and an alkylene group, or the like.

The alkyl group represented by R in Formula (G) to Formula (H) is preferably an alkyl group having from 1 to 10 carbon atoms, more preferably an alkyl group having from 1 to 5 carbon atoms, still more preferably an alkyl group having 1 or 2 carbon atoms.

Specific examples of the alkyl group represented by R in Formula (G) to Formula (H) include a methyl group, an ethyl group, an n-propyl group, an isopropyl group, an n-butyl group, an isobutyl group, an s-butyl group, or a t-butyl group.

The alkoxy group represented by R in Formula (G) to Formula (H) is preferably an alkoxy group having from 1 to 10 carbon atoms, more preferably an alkoxy group having from 1 to 5 carbon atoms, still more preferably an alkoxy group having 1 or 2 carbon atoms.

Specific examples of the alkoxy group represented by R in Formula (G) to Formula (H) include a methoxy group, an ethoxy group, an n-propoxy group, an isopropoxy group, an n-butoxy group, an isobutoxy group, an s-butoxy group, or a t-butoxy group.

The alkyl halide group represented by R in Formula (G) to Formula (H) is preferably an alkyl halide group having from 1 to 5 carbon atoms, more preferably an alkyl halide group having from 1 to 3 carbon atoms, still more preferably an alkyl halide group having 1 or 2 carbon atoms.

Specific examples of the alkyl halide group represented by R in Formula (G) to Formula (H) include the alkyl group represented by R in Formula (G) to Formula (H), in which at least one hydrogen atom contained is substituted with a halogen atom such as a fluorine atom or a chlorine atom. In particular, a fluoromethyl group, a difluoromethyl group, a trifluoromethyl group, or the like is preferred.

Each n in Formula (G) to Formula (H) is independently preferably 0 to 2, more preferably 0 or 1, still more preferably 0.

Specific examples of the divalent aliphatic group represented by Y include a linear or branched alkylene group, a cycloalkylene group, or a divalent group having a polyalkylene oxide structure.

The linear or branched alkylene group represented by Y is preferably an alkylene group having from 1 to 20 carbon atoms, more preferably an alkylene group having from 1 to 15 carbon atoms, still more preferably an alkylene group having from 1 to 10 carbon atoms.

Specific examples of the alkylene group represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, or a 2-methyldecamethylene group.

The cycloalkylene group represented by Y is preferably a cycloalkylene group having from 3 to 10 carbon atoms, more preferably a cycloalkylene group having from 3 to 6 carbon atoms.

Specific examples of the cycloalkylene group represented by Y include a cyclopropylene group or a cyclohexylene group.

The unit structure contained in the divalent group having the polyalkylene oxide structure represented by Y is preferably an alkylene oxide structure having from 1 to 10 carbon atoms, more preferably an alkylene oxide structure having from 1 to 8 carbon atoms, still more preferably an alkylene oxide structure having from 1 to 4 carbon atoms. In particular, the polyalkylene oxide structure is preferably a polyethylene oxide structure or a polypropylene oxide structure. The alkylene group in the alkylene oxide structure may be linear or branched. The unit structure in the polyalkylene oxide structure may be adopted singly or in combination of two or more kinds thereof.

The divalent organic group represented by Y may be a divalent group having a polysiloxane structure. Examples of the divalent group having the polysiloxane structure represented by Y include a divalent group having a polysiloxane structure, in which a silicon atom in the polysiloxane structure is bound with a hydrogen atom, an alkyl group having from 1 to 20 carbon atoms, or an aryl group having from 6 to 18 carbon atoms.

Specific examples of the alkyl group having from 1 to 20 carbon atoms, in which the group is bound with a silicon atom in the polysiloxane structure, include a methyl group, an ethyl group, an n-propyl group, an isopropyl group, an n-butyl group, a t-butyl group, an n-octyl group, a 2-ethylhexyl group, or an n-dodecyl group. In particular, a methyl group is preferred.

The aryl group having from 6 to 18 carbon atoms, in which the group is bound with a silicon atom in the polysiloxane structure, may be unsubstituted, or may be substituted with a substituent. In a case in which the aryl group has a substituent, specific examples of the substituent include a halogen atom, an alkoxy group, or a hydroxy group. Specific examples of the aryl group having from 6 to 18 carbon atoms include a phenyl group, a naphthyl group, or a benzyl group. In particular, a phenyl group is preferred.

The alkyl group having from 1 to 20 carbon atoms or the aryl group having from 6 to 18 carbon atoms in the polysiloxane structure may be adopted singly or in combination of two or more kinds thereof.

A silicon atom constituting the divalent group having the polysiloxane structure represented by Y may be bound with an NH group in Formula (1) via an alkylene group such as a methylene group or an ethylene group, or an arylene group such as a phenylene group.

The group represented by Formula (G) is preferably a group represented by the following Formula (G′), and the group represented by Formula (H) is preferably a group represented by the following Formula (H′), Formula (H″) or Formula (H′″).

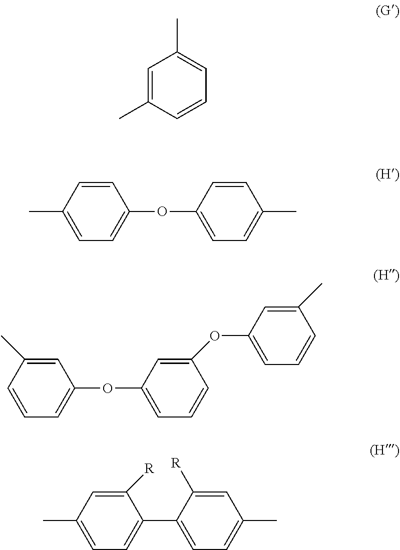

In Formula (H′″), each R independently represents an alkyl group, an alkoxy group, an alkyl halide group, a phenyl group, or a halogen atom. R is preferably an alkyl group, more preferably a methyl group.

A combination of the tetravalent organic group represented by X and the divalent organic group represented by Y in Formula (1) is not particularly limited. Examples of the combination of the tetravalent organic group represented by X and the divalent organic group represented by Y include a combination of X which represents the group represented by Formula (F) or the group represented by Formula (P) and Y which represents the group represented by Formula (G), or a combination of X which represents the group represented by Formula (P) and the group represented by Formula (F) used in combination and Y which represents the group represented by Formula (G), from the viewpoint that the thermal expansion coefficient of a cured product to be formed is 50 ppm/K or less. In a case in which X represents the group represented by Formula (P) and the group represented by Formula (F) used in combination, the ratio on a molar basis between the group represented by Formula (P) and the group represented by Formula (F) (the ratio (P:F) between the group represented by Formula (P): the group represented by Formula (F)) is preferably from 50:50 to 20:80, more preferably from 30:70 to 20:80.

Each of R⁶ and R⁷ independently represents a hydrogen atom or a monovalent organic group. In a case in which each of R⁶ and R⁷ represents a monovalent organic group, the monovalent organic group may have a polymerizable unsaturated bond.

The monovalent organic group is preferably an aliphatic hydrocarbon group having from 1 to 4 carbon atoms or an organic group having an unsaturated double bond, more preferably any of a group represented by the following Formula (2), an ethyl group, an isobutyl group, or a t-butyl group, and still more preferably contains an aliphatic hydrocarbon group having from 1 or 2 carbon atoms or a group represented by the following Formula (2).

The monovalent organic group contains an organic group having an unsaturated double bond, preferably a group represented by the following Formula (2), whereby a cured product tends to be able to be formed which is high in transmittance of i-line and also favorable during curing at a low temperature of 400° C. or less. In a case in which the monovalent organic group contains an organic group having an unsaturated double bond, preferably a group represented by the following Formula (2), an unsaturated double bond portion is at least partially detached by a compound (C).

Specific examples of the aliphatic hydrocarbon group having from 1 to 4 carbon atoms include a methyl group, an ethyl group, an n-propyl group, an isopropyl group, an n-butyl group, or a t-butyl group, and in particular, an ethyl group, an isobutyl group, or a t-butyl group is preferred.

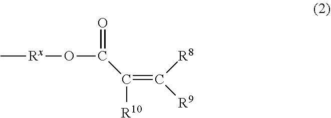

In Formula (2), each of R⁸ to R¹⁰ independently represents a hydrogen atom or an aliphatic hydrocarbon group having from 1 to 3 carbon atoms, and RY represents a divalent linking group.

The number of carbon atoms of the aliphatic hydrocarbon group represented by R⁸ to R¹⁰ in Formula (2) is from 1 to 3, preferably 1 or 2. Specific examples of the aliphatic hydrocarbon group represented by each of R⁸ to R¹⁰ include a methyl group, an ethyl group, an n-propyl group, or an isopropyl group, and a methyl group is preferred.

The combination of R⁸ to R¹⁰ in Formula (2) is preferably a combination in which R⁸ and R⁹ are each a hydrogen atom, and R¹⁰ is a hydrogen atom or a methyl group.

R^{x} in Formula (2) is a divalent linking group, preferably a hydrocarbon group having from 1 to 10 carbon atoms. Examples of the hydrocarbon group having from 1 to 10 carbon atoms include a linear or branched alkylene group.

The number of carbon atoms in R^{x} is preferably from 1 to 10, more preferably from 2 to 5, still more preferably 2 or 3.

In Formula (1), at least one of R⁶ or R⁷ is preferably the group represented by Formula (2), and both R⁶ and R⁷ are each more preferably the group represented by Formula (2).

In a case in which the polyimide precursor (A) includes a compound having the structure unit represented by Formula (1), the proportion of R⁶ and R⁷ as the group represented by Formula (2) with respect to the total of R⁶ and R⁷ in the entire structure unit contained in the compound is preferably 60% by mol or more, more preferably 70% by mol or more, still more preferably 80% by mol or more. The upper limit is not particularly limited, and may be 100% by mol.

The proportion may be from 0% by mol to less than 60% by mol.

The group represented by Formula (2) is preferably a group represented by the following Formula (2′).

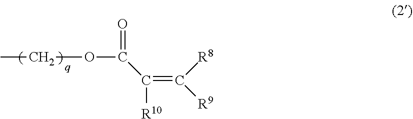

In Formula (2′), each of R⁸ to R¹⁰ independently represents a hydrogen atom or an aliphatic hydrocarbon group having from 1 to 3 carbon atoms, and q represents an integer of from 1 to 10.

In Formula (2′), q is an integer of from 1 to 10, preferably an integer of from 2 to 5, more preferably 2 or 3.

The content rate of the structure unit represented by Formula (1) with respect to the entire structure unit contained in the compound having the structure unit represented by Formula (1) is preferably 60% by mol or more, more preferably 70% by mol or more, still more preferably 80% by mol or more. The upper limit of the content rate is not particularly limited, and may be 100% by mol.

The polyimide precursor (A) may be synthesized with tetracarboxylic dianhydride and a diamine compound. In this case, in Formula (1), X corresponds to a residue derived from the tetracarboxylic dianhydride, and Y corresponds to a residue derived from the diamine compound. The polyimide precursor (A) may be synthesized with tetracarboxylic acid instead of the tetracarboxylic dianhydride.

Specific examples of the tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-biphenyl ether tetracarboxylic dianhydride, 3,3′,4,4′-benzophenonetetracarboxylic dianhydride, 1,2,5,6-naphthalenetetracarboxylic dianhydride, 2,3,5,6-pyridinetetracarboxylic dianhydride, 1,4,5,8-naphthalenetetracarboxylic dianhydride, 3,4,9,10-perylenetetracarboxylic dianhydride, m-terphenyl-3,3′,4,4′-tetracarboxylic dianhydride, p-terphenyl-3,3′,4,4′-tetracarboxylic dianhydride, 1,1,1,3,3,3-hexafluoro-2,2-bis(2,3-dicarboxyphenyl) propane dianhydride, 1,1,1,3,3,3-hexafluoro-2,2-bis(3,4-dicarboxyphenyl) propane dianhydride, 2,2-bis(2,3-dicarboxyphenyl) propane dianhydride, 2,2-bis(3,4-dicarboxyphenyl) propane dianhydride, 2,2-bis {4′-(2,3-dicarboxyphenoxy)phenyl}propane dianhydride, 2,2-bis {4′-(3,4-dicarboxyphenoxy)phenyl}propane dianhydride, 1,1,1,3,3,3-hexafluoro-2,2-bis {4′-(2,3-dicarboxyphenoxy)phenyl}propane dianhydride, 1,1,1,3,3,3-hexafluoro-2,2-bis {4′-(3,4-dicarboxyphenoxy)phenyl}propane dianhydride, 4,4′-oxydiphthalic dianhydride, 4,4′-sulfonyldiphthalic dianhydride, 9,9-bis(3,4-dicarboxyphenyl) fluorene dianhydride, or octahydro-3H,3″H-dispiro[4,7]methanoisobenzofuran-5,1′-cyclopentane-3′,5″-[4,7]methanoisobenzofuran]-1,1″,2′,3,3″ (4H,4″H)-pentaone (CpODA).

The tetracarboxylic dianhydride may be used singly, or in combination of two or more kinds thereof.

Specific examples of the diamine compound include 2,2′-dimethylbiphenyl-4,4′-diamine, 2,2′-bis(trifluoromethyl)-4,4′-diaminobiphenyl, 2,2′-difluoro-4,4′-diaminobiphenyl, p-phenylenediamine, m-phenylenediamine, p-xylylenediamine, m-xylylenediamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenylsulfone, 3,4′-diaminodiphenylsulfone, 3,3′-diaminodiphenylsulfone, 2,4′-diaminodiphenylsulfone, 2,2′-diaminodiphenylsulfone, 4,4′-diaminodiphenylsulfide, 3,4′-diaminodiphenylsulfide, 3,3′-diaminodiphenylsulfide, 2,4′-diaminodiphenylsulfide, 2,2′-diaminodiphenylsulfide, o-tolidine, o-tolidinesulfone, 4,4′-methylenebis(2,6-diethylaniline), 4,4′-methylenebis(2,6-diisopropylaniline), 2,4-diaminomesitylene, 1,5-diaminonaphthalene, 4,4′-benzophenonediamine, bis-{4-(4′-aminophenoxy)phenyl}sulfone, 2,2-bis {4-(4′-aminophenoxy)phenyl}propane, 3,3′-dimethyl-4,4′-diaminodiphenylmethane, 3,3′,5,5′-tetramethyl-4,4′-diaminodiphenylmethane, bis {4-(3′-aminophenoxy)phenyl}sulfone, 2,2-bis(4-aminophenyl) propane, 9,9-bis(4-aminophenyl) fluorene, 1,3-bis(3-aminophenoxy)benzene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-diaminoheptane, 2-methyl-1,8-diaminooctane, 2-methyl-1,9-diaminononane, 2-methyl-1,10-diaminodecane, 1,4-cyclohexanediamine, 1,3-cyclohexanediamine, or diaminopolysiloxane. The diamine compound is preferably 2,2′-dimethylbiphenyl-4,4′-diamine, m-phenylenediamine, 4,4′-diaminodiphenyl ether, or 1,3-bis(3-aminophenoxy)benzene. The diamine compound may be used singly, or in combination of two or more kinds thereof.

The compound having the structure unit represented by Formula (1), in which at least one of R⁶ or R⁷ in Formula (1) is a monovalent organic group, can be obtained by, for example, the following method (a) or (b).

(a) A tetracarboxylic dianhydride (preferably, tetracarboxylic dianhydride represented by the following Formula (8)) and a compound represented by R—OH are reacted in an organic solvent, to provide a diester derivative, and then the diester derivative and a diamine compound represented by H₂N—Y—NH₂ are condensed.

(b) A tetracarboxylic dianhydride and a diamine compound represented by H₂N—Y—NH₂ are reacted in an organic solvent, to provide a polyamide acid solution, and a compound represented by R—OH is added to the polyamide acid solution, and reacted in the organic solvent, to introduce an ester group.

Y in the diamine compound represented by H₂N—Y—NH₂ is the same as Y in Formula (1), and the same also applies to specific examples and preferred examples. R in the compound represented by R—OH represents a monovalent organic group, and specific examples and preferred examples thereof are respectively the same as specific examples and preferred examples of R⁶ and R⁷ in Formula (1).

Each of the tetracarboxylic dianhydride represented by Formula (8), the diamine compound represented by H₂N—Y—NH₂, and the compound represented by R—OH may be used singly, or in combination of two or more kinds thereof.

Examples of the organic solvent include N-methyl-2-pyrrolidone, γ-butyrolactone, dimethoxyimidazolidinone, or 3-methoxy-N,N-dimethylpropionamide, and in particular, 3-methoxy-N,N-dimethylpropionamide is preferred.

The polyimide precursor may be synthesized by allowing a dehydration-condensation agent to act on the polyamide acid solution together with the compound represented by R—OH. The dehydration-condensation agent preferably includes at least one selected from the group consisting of trifluoroacetic anhydride, N,N′-dicyclohexylcarbodiimide (DCC) and 1,3-diisopropylcarbodiimide (DIC).

The above compound included in the polyimide precursor (A) can be obtained by allowing the compound represented by R—OH to act on a tetracarboxylic dianhydride represented by the following Formula (8), to provide a diester derivative, thereafter allowing a chlorinating agent such as thionyl chloride to act for conversion into an acid chloride, and then reacting the diamine compound represented by H₂N—Y—NH₂ and the acid chloride.

The above compound included in the polyimide precursor (A) can be obtained by allowing the compound represented by R—OH to act on a tetracarboxylic dianhydride represented by the following Formula (8), to provide a diester derivative, and thereafter reacting the diamine compound represented by H₂N—Y—NH₂ and the diester derivative in the presence of a carbodiimide compound.

The above compound included in the polyimide precursor (A) can be obtained by reacting a tetracarboxylic dianhydride represented by the following Formula (8) and the diamine compound represented by H₂N—Y—NH₂, to provide a polyamide acid, thereafter iso-imidating the polyamide acid in the presence of a dehydration-condensation agent such as trifluoroacetic anhydride, and then allowing the compound represented by R—OH to act. Alternatively, the compound represented by R—OH may also be allowed to act on a part of the tetracarboxylic dianhydride in advance, thereby reacting the tetracarboxylic dianhydride partially esterified, and the diamine compound represented by H₂N—Y—NH₂.

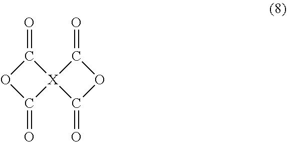

X in Formula (8) is the same as X in Formula (1), and the same also applies to specific examples and preferred examples thereof.

The compound represented by R—OH used for synthesis of the above compound included in the polyimide precursor (A) may be a compound in which a hydroxy group is bound to RY in the group represented by Formula (2), a compound in which a hydroxy group is bound to a terminal methylene group of the group represented by Formula (2′), or the like. Specific examples of the compound represented by R—OH include methanol, ethanol, n-propanol, isopropanol, n-butanol, 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, or 4-hydroxybutyl methacrylate, and in particular, 2-hydroxyethyl methacrylate and 2-hydroxyethyl acrylate is preferred.

The compound having the structure unit represented by Formula (1), in which both R⁶ and R⁷ in Formula (1) are each a hydrogen atom, can be produced by an ordinary method.

The molecular weight of the polyimide precursor (A) is not particularly restricted, and, for example, the weight average molecular weight is preferably from 10,000 to 200,000, more preferably from 10,000 to 100,000.

The weight average molecular weight can be measured by, for example, a gel permeation chromatography method, and can be determined by conversion with a standard polystyrene calibration curve.

The insulation film forming material may further include a dicarboxylic acid, and the polyimide precursor (A) included in the insulation film forming material may have a structure formed by reaction of some amino groups in the polyimide precursor (A) with carboxy groups in the dicarboxylic acid. For example, when the polyimide precursor is synthesized, some amino groups in the diamine compound and carboxy groups in the dicarboxylic acid may be reacted.

The dicarboxylic acid may be a dicarboxylic acid having a (meth)acrylic group, or may be, for example, a dicarboxylic acid represented by the following formula. When the polyimide precursor (A) is synthesized, some amino groups in the diamine compound and carboxy groups in the dicarboxylic acid can be reacted to introduce a dicarboxylic acid-derived methacrylic group into the polyimide precursor (A).

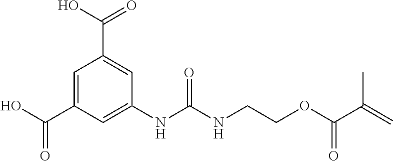 [SMILES: C=C(C)C(=O)OCCNC(=O)Nc1cc(C(=O)O)cc(C(=O)O)c1]

The insulation film forming material may include a polyimide resin, in addition to the polyimide precursor (A). The polyimide precursor and the polyimide resin are combined, whereby a volatile can be suppressed from being generated by cyclodehydration in imide ring formation, and therefore, void generation tends to be able to be suppressed. The polyimide resin mentioned here refers to a resin having an imide backbone in the entire resin backbone or a part thereof. The polyimide resin is preferably soluble in a solvent in the insulation film forming material with the polyimide precursor.

The polyimide resin is not particularly limited as long as it is a polymer compound having a plurality of structure units each containing an imide bond, and preferably includes, for example, a compound having a structure unit represented by the following Formula (X). Thus, a semiconductor device including an insulation film exhibiting high reliability tends to be obtained.

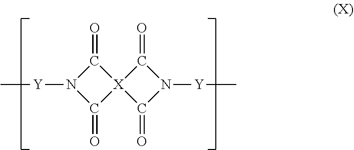

In Formula (X), X represents a tetravalent organic group, and Y represents a divalent organic group. Preferred examples of the substituents X and Y in Formula (X) are respectively the same as preferred examples of the substituents X and Y in Formula (1) described above.

In a case in which the insulation film forming material includes the polyimide resin, the proportion of the polyimide resin with respect to the total of the polyimide precursor and the polyimide resin may be from 15% by mass to 50% by mass, or may be from 10% by mass to 20% by mass.

The insulation film forming material may include any other resin than the polyimide precursor (A) and the polyimide resin. Examples of such any other resin include a novolac resin, an acrylic resin, a polyethernitrile resin, a polyethersulfone resin, an epoxy resin, a polyethylene terephthalate resin, a polyethylene naphthalate resin, or a polyvinyl chloride resin from the viewpoint of heat resistance. Such any other resin may be used singly, or in combination of two or more kinds thereof.

The content rate of the polyimide precursor (A) with respect to the amount of the total resin component in the insulation film forming material is preferably from 50% by mass to 100% by mass, more preferably from 70% by mass to 100% by mass, still more preferably from 90% by mass to 100% by mass.

### (Solvent (B))

The insulation film forming material includes a solvent (B) (hereinafter, also referred to as “component (B)”.). The component (B) preferably includes at least one selected from the group consisting of compounds represented by the following Formula (3) to Formula (7).

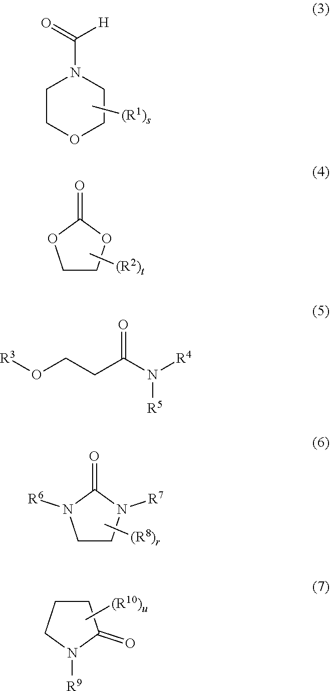

In Formulae (3) to (7), each of R¹, R², R⁸ and R¹⁰ is independently an alkyl group having from 1 to 4 carbon atoms, and each of R³ to R⁷ and R⁹ is independently a hydrogen atom or an alkyl group having from 1 to 4 carbon atoms. s is an integer of from 0 to 8, tis an integer of from 0 to 4, r is an integer of from 0 to 4, and u is an integer of from 0 to 3.

In Formula (3), s is preferably 0.

In Formula (4), the alkyl group having from 1 to 4 carbon atoms in R² is preferably a methyl group or an ethyl group. t is preferably 0, 1 or 2, more preferably 1.

In Formula (5), the alkyl group having from 1 to 4 carbon atoms in R³ is preferably a methyl group, an ethyl group, a propyl group, or a butyl group. The alkyl group having from 1 to 4 carbon atoms in R⁴ and R⁵ is preferably a methyl group or an ethyl group.

In Formula (6), the alkyl group having from 1 to 4 carbon atoms in R⁶ to R⁸ is preferably a methyl group or an ethyl group. r is preferably 0 or 1, more preferably 0.

In Formula (7), the alkyl group having from 1 to 4 carbon atoms in R⁹ and R¹⁰ is preferably a methyl group or an ethyl group. u is preferably 0 or 1, more preferably 0.

The component (B) may be, for example, at least one of any compound represented by Formula (4), (5), (6) or (7), or may be a compound represented by Formula (5) or a compound represented by Formula (7).

Specific examples of the component (B) include the following compounds.

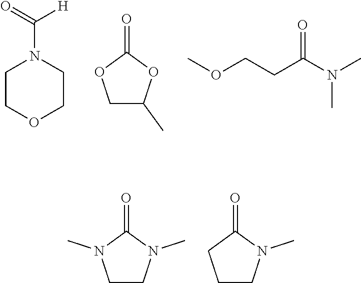

The component (B) included in the insulation film forming material is not limited to the above compounds, and may be any other solvent. The component (B) may be an ester-based solvent, an ether-based solvent, a ketone-based solvent, a hydrocarbon-based solvent, an aromatic hydrocarbon-based solvent, a sulfoxide-based solvent, or the like.

Examples of the ester-based solvent include ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, γ-butyrolactone, ¿-caprolactone, 8-valerolactone, alkyl alkoxyacetate (for example, methyl methoxyacetate, ethyl methoxyacetate, butyl methoxyacetate, methyl ethoxyacetate, or ethyl ethoxyacetate) such as methyl alkoxyacetate, ethyl alkoxyacetate, or butyl alkoxyacetate, 3-alkoxypropionic acid alkyl ester (for example, methyl 3-methoxypropionate, ethyl 3-methoxypropionate, methyl 3-ethoxypropionate and ethyl 3-ethoxypropionate) such as methyl 3-alkoxypropionate or ethyl 3-alkoxypropionate, 2-alkoxypropionic acid alkyl ester (for example, methyl 2-methoxypropionate, ethyl 2-methoxypropionate, propyl 2-methoxypropionate, methyl 2-ethoxypropionate, or ethyl 2-ethoxypropionate) such as methyl 2-alkoxypropionate, ethyl 2-alkoxypropionate, or propyl 2-alkoxypropionate, methyl 2-alkoxy-2-methylpropionate such as methyl 2-methoxy-2-methylpropionate, ethyl 2-alkoxy-2-methylpropionate such as ethyl 2-ethoxy-2-methylpropionate, methyl pyruvate, ethyl pyruvate, propyl pyruvate, methyl acetoacetate, ethyl acetoacetate, methyl 2-oxobutanoate, or ethyl 2-oxobutanoate.

Examples of the ether-based solvent include diethylene glycol dimethyl ether, tetrahydrofuran, ethylene glycol monomethyl ether, ethylene glycol monoethyl ether, methylcellosolve acetate, ethylcellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, or propylene glycol monopropyl ether acetate.

Examples of the ketone-based solvent include methyl ethyl ketone, cyclohexanone, cyclopentanone, 2-heptanone, 3-heptanone, or N-methyl-2-pyrrolidone (NMP).

Examples of the hydrocarbon-based solvent include limonene.

Examples of the aromatic hydrocarbon-based solvent include toluene, xylene, or anisole.

Examples of the sulfoxide-based solvent include dimethylsulfoxide.

Examples of the solvent of the component (B) preferably include γ-butyrolactone, cyclopentanone, or ethyl lactate.

The content rate of NMP in the insulation film forming material may be 1% by mass or less with respect to the total amount of the insulation film forming material, and may be 3% by mass or less with respect to the total amount of the polyimide precursor (A), from the viewpoint of a reduction in toxicity such as reprotoxy and from the viewpoint of a reduction in environmental load.

The content of the component (B) in the insulation film forming material is preferably from 1 part by mass to 10000 parts by mass, more preferably from 50 parts by mass to 10000 parts by mass with respect to 100 parts by mass of the polyimide precursor (A)

The component (B) preferably includes at least one of a solvent (1) which is at least one selected from the group consisting of the compounds represented by Formula (3) to Formula (6), or a solvent (2) which is at least one selected from the group consisting of an ester-based solvent, an ether-based solvent, a ketone-based solvent, a hydrocarbon-based solvent, an aromatic hydrocarbon-based solvent, and a sulfoxide-based solvent.

The content rate of the solvent (1) may be from 5% by mass to 100% by mass, or may be from 5% by mass to 50% by mass with respect to the total of the solvent (1) and the solvent (2).

The content of the solvent (1) may be from 10 parts by mass to 1000 parts by mass, may be from 10 parts by mass to 100 parts by mass, or may be from 10 parts by mass to 50 parts by mass with respect to 100 parts by mass of the polyimide precursor (A).

### (Compound (C))

A second insulation film forming material may contain a compound (C). The compound (C) acts on a polymerizable unsaturated bond site in the polyimide precursor (A), and promotes detachment of the polymerizable unsaturated bond site.

Examples of the compound (C) include a nitrogen-containing compound. The nitrogen-containing compound may be a thermal base generator. The thermal base generator is heated to generate a base, and the base promotes detachment of an unsaturated bond site of the polyimide precursor (A).

Specific examples of the nitrogen-containing compound include aniline diacetic acid, 2-(methylphenylamino) ethanol, 2-(ethylanilino) ethanol, N-phenyldiethanolamine, N-methylaniline, N-ethylaniline, N,N′-dimethylaniline, N-phenylethanolamine, 4-phenylmorpholine, 2,2′-(4-methylphenylimino) diethanol, 4-aminobenzamide, 2-aminobenzamide, nicotinamide, 4-amino-N-methylbenzamide, 4-aminoacetanilide, 4-aminoacetophenone, diazabicycloundecene, or any salt thereof, and, in particular, aniline diacetic acid, 4-aminobenzamide, nicotinamide, diazabicycloundecene, N-phenyldiethanolamine, N-methylaniline, N-ethylaniline, N,N′-dimethylaniline, N-phenylethanolamine, 4-phenylmorpholine, 2,2′-(4-methylphenylimino) diethanol, any salt thereof, or the like is preferred. The nitrogen-containing compound may be used singly, or in combination of two or more kinds thereof.

The content of the compound (C) is preferably 0.1 parts by mass to 20 parts by mass with respect to 100 parts by mass of the polyimide precursor (A), and is more preferably from 0.3 parts by mass to 15 parts by mass, still more preferably from 0.5 parts by mass to 10 parts by mass from the viewpoint of storage stability.

The insulation film forming material includes the polyimide precursor (A) and the solvent (B), and includes, if necessary, the compound (C), a photo-polymerization initiator (D), a polymerizable monomer (E), a thermal polymerization initiator (F), a polymerization inhibitor (G), an antioxidant, a coupling agent, a surfactant, a leveling agent, a rust inhibitor, and/or the like, and may include any other component and unavoidable impurities as long as the effects of the disclosure are not impaired. The insulation film forming material preferably further includes a component (D) and a component (E).

Hereinafter, the compound (C) is also referred to as “component (C)”, the photo-polymerization initiator (D) is also referred to as “component (D)”, the polymerizable monomer (E) is also referred to as “component (E)”, the thermal polymerization initiator (F) is also referred to as “component (F)”, and the polymerization inhibitor (G) is also referred to as “component (G)”.

In one embodiment, for example, 80% by mass or more, 90% by mass or more, 95% by mass or more, 98% by mass or more, or 100% by mass of the insulation film forming material may be configured from at least any one selected from the group consisting of
the polyimide precursor (A) to the component (B),
the polyimide precursor (A) to the component (B) and the component (D) to the component (E),
the polyimide precursor (A) to the component (B) and the component (D) to the component (F),
the polyimide precursor (A) to the component (B) and the component (D) to the component (G),
the polyimide precursor (A) to the component (B) and the component (D) to the component (G) and the component (C), an antioxidant, a coupling agent, a surfactant, a leveling agent, and a rust inhibitor.

In another embodiment, for example, 80% by mass or more, 90% by mass or more, 95% by mass or more, 98% by mass or more, or 100% by mass of the insulation film forming material may be configured from at least any one selected from the group consisting of
the polyimide precursor (A) to the component (B) and the component (E) to the component (F),
the polyimide precursor (A) to the component (B) and the component (E) to the component (G),
the polyimide precursor (A) to the component (B) and the component (E) to the component (G) and the component (C), an antioxidant, a coupling agent, a surfactant, a leveling agent, and a rust inhibitor.

Any component conventionally known may be appropriately used as each of the photo-polymerization initiator (D), the polymerizable monomer (E), the thermal polymerization initiator (F), the polymerization inhibitor (G), the antioxidant, the coupling agent, the surfactant, the leveling agent, the rust inhibitor, and the like.

### EXAMPLES

Hereinafter, the disclosure is further specifically described with reference to Examples and Comparative Examples. The disclosure is not limited to the following Examples.

### (Synthesis of Polyimide Precursor A1)

6.71 g of 3,3′,4,4′-biphenyltetracarboxylic dianhydride (BPDA) and 2.09 g of p-phenylenediamine (PPD) were dissolved in 30 g of 3-methoxy-N,N-dimethylpropanamide. The resulting solution was stirred at 30° C. for 2 hours, and thus a polyimide precursor A1 was obtained (hereinafter, designated as “polymer A1”). The polymer A1 obtained was dropped into dehydrated ethanol, a precipitated product was separated by filtration and collected, and dried under reduced pressure, and thus a powder of the polymer A1 was obtained. The weight average molecular weight of the polymer A1 was determined in terms of standard polystyrene with a gel permeation chromatography (GPC) method. The weight average molecular weight of the polymer A1 was 20,000.

### (Synthesis of Polyimide Precursor A2)

7.07 g of 3,3′,4,4′-biphenyl ether tetracarboxylic dianhydride (ODPA) and 4.12 g of 2,2′-dimethylbiphenyl-4,4′-diamine (DMAP) were dissolved in 30 g of 3-methoxy-N,N-dimethylpropanamide. The resulting solution was stirred at 30° C. for 4 hours, and thus polyamide acid was obtained. After 9.45 g of trifluoroacetic anhydride was added thereto at room temperature (25° C.), 7.08 g of 2-hydroxyethyl methacrylate (HEMA) was added, and stirred at 45° C. for 10 hours. This reaction liquid was dropped into distilled water, a precipitated product was separated by filtration and collected, and dried under reduced pressure, and thus a polyimide precursor A2 was obtained (hereinafter, designated as “polymer A2”). The weight average molecular weight of the polymer A2, determined by a GPC method (in terms of standard polystyrene), was 20,000.

### (Synthesis of Polyimide Precursor A3)

A polyimide precursor A3 was obtained (hereinafter, designated as “polymer A3”) by the same operation as in synthesis of the polyimide precursor A2 except that DMAP was changed to 3.6 g of 4,4′-diaminodiphenyl ether (ODA) and 0.2 g of m-phenylenediamine (MPD). The weight average molecular weight of the polymer A3, determined by a GPC method (in terms of standard polystyrene), was 25,000.

### (Synthesis of Polyimide Precursor A4)

8.76 g of octahydro-3H,3″H-dispiro[[4,7]methanoisobenzofuran-5,1′-cyclopentane-3′,5″-[4,7]methanoisobenzofuran]-1,1″,2′,3,3″ (4H,4″H)-pentaone (CpODA) and 2.09 g of PPD were dissolved in 30 g of 3-methoxy-N,N-dimethylpropanamide. The resulting solution was stirred at 30° C. for 2 hours, and thus a polyimide precursor A4 was obtained (hereinafter, designated as “polymer A4”). The polymer A4 obtained was dropped into dehydrated ethanol, a precipitated product was separated by filtration and collected, and dried under reduced pressure, and thus a powder of the polymer A4 was obtained. The weight average molecular weight of the polymer A4 was determined in terms of standard polystyrene with a gel permeation chromatography (GPC) method. The weight average molecular weight of the polymer A4 was 20,000.

### (Synthesis of Polyimide Precursor A5)

A reaction mixture was obtained by dissolving 15.5 g of ODPA and 13.1 g of HEMA in 50 mL of γ-butyrolactone in a reaction container, stirring them under a condition of 25° C., and adding 8 g of pyridine with stirring. After completion of generation of heat by the reaction, the reaction mixture was cooled to 25° C. and left to still stand for 15 hours.

Next, a solution in which 20 g of dicyclohexylcarbodiimide (DCC) was suspended in 180 mL of γ-butyrolactone was added to the reaction mixture with stirring over 40 minutes under ice cooling. Next, a suspension in which 9.3 g of 4,4′-diaminodiphenyl ether was suspended in 35 mL of γ-butyrolactone was added to the reaction mixture with stirring over 60 minutes. The reaction mixture was further stirred at 25° C. for 2 hours, thereafter 30 mL of ethyl alcohol was added thereto and stirred for 1 hour, and then 40 mL of γ-butyrolactone was added to the reaction mixture. A precipitated product generated in the reaction mixture was removed by filtration, and thus a reaction liquid was obtained.

The reaction liquid obtained was added to 3 L of ethyl alcohol, and thus a precipitated product including a crude polymer was produced. The crude polymer produced was separated by filtration, and dissolved in 1 L of tetrahydrofuran, and thus a crude polymer solution was obtained. The crude polymer solution obtained was dropped into water, to precipitate the polymer, the resulting precipitated product was separated by filtration and then dried under reduced pressure, and thus a polyimide precursor A5 as a powdery polymer was obtained (hereinafter, designated as “polymer A5”). The weight average molecular weight of the polymer A5, determined by a GPC method (in terms of standard polystyrene), was 35,000.

### (Synthesis of Polyimide Precursor A6)

A polyimide precursor A6 was obtained (hereinafter, designated as “polymer A6”) by the same operation as in the synthesis method of the polyimide precursor A5 except that 15.5 g of ODPA was changed to 14.7 g of BPDA. The weight average molecular weight of the polymer A6, determined by a GPC method (in terms of standard polystyrene), was 28,000.

The weight average molecular weights of the polymers A1 to A6 were each determined in terms of standard polystyrene with a gel permeation chromatography (GPC) method. Specifically, a solution in which 0.5 mg of the polyimide precursor was dissolved in 1 mL of a solvent [tetrahydrofuran (THF)/dimethylformamide (DMF)=1/1 (volume ratio)] was used, and measurement was made under the following conditions.

### (Measurement Conditions)

Measurement apparatus: SPD-M20A, Shimadzu Corporation
Pump: LC-20AD, Shimadzu Corporation
Column oven: CTO-20A, Shimadzu Corporation
Measurement conditions: column Gelpack GL-S300MDT-5×2
Eluent: THF/DMF=1/1 (volume ratio)
   LiBr (0.03 mol/L), H₃PO₄ (0.06 mol/L)
   Flow rate: 1.0 mL/min, detector: UV270 nm, column temperature: 40° C.
   Standard polystyrene: calibration curve created by TSKgel standard Polystyrene Types F-1, F-4, F-20, F-80, and A-2500 manufactured by Tosoh Corporation

### Examples 1 to 6 and Comparative Example 1

### (Preparation of Insulation Film Forming Material)

Each insulation film forming material of Examples 1 to 6 and Comparative Example 1 was prepared as described below, with components and the amounts thereof compounded shown in Table 1. The unit of the amount of each component compounded, in Table 1, is “parts by mass”. Each blank cell in Table 1 means no compounding of the corresponding component. A mixture of components was kneaded in a common solvent-resistant container at room temperature (25° C.) overnight and then filtrated under pressure with a filter having pores of 0.2 μm in each of Examples and Comparative Examples. The resulting insulation film forming material was used and the following evaluations were performed.

Each component in Table 1 is described below.

### Polyimide Precursor

Polymers A1 to A6 described above

### Solvent

B1: 3-methoxy-N,N-dimethylpropanamide
B2: γ-butyrolactone
B3: dimethylsulfoxide

### Polymerizable Monomer

C1: tetraethylene glycol dimethacrylate (TEGDMA)
C2: tricyclodecanedimethanol diacrylate (A-DCP)·
   Rust inhibitor
D1: benzotriazole (BT)·

### Polymerization Initiator

E1: 1-phenyl-1,2-propanedione-2-(o-ethoxycarbonyl) oxime (PDO)
E2: 4,4′-bis(diethylamino)benzophenone (EMK)
E3: bis(1-phenyl-1-methylethyl) peroxide (PercumyID)·

### Antioxidant

F1: N,N′-(hexane-1,6-diyl)bis[3-(3,5-di-tert-butyl-4-hydroxyphenyl) propanamide] (HP300)

### Adhesion Aid

G1: 3-ureidopropyltriethoxysilane (UCT-801)

### (Measurement of Thermal Expansion Coefficient of Cured Film)

A cured film was formed as described below, with the insulation film forming material in each of Examples 1 to 6 and Comparative Example 1, and then the thermal expansion coefficient was measured. A resin film was formed so that the thickness after curing was about 10 μm, by spin-coating a Si substrate with the insulation film forming material, and heating and drying the resultant on a hot plate at 95° C. for 120 seconds and then at 105° C. for 120 seconds.

In each of Examples 1 and 4, the resulting resin film was cured with a vertical diffusion furnace μ-TF under a nitrogen atmosphere at a curing temperature for a curing time as described in Table 1, and thus a cured product having a thickness of 10 μm was obtained. The cured product obtained was immersed in an aqueous 4.9% by mass hydrofluoric acid solution, and thus the cured product was released from the Si substrate. The cured product obtained was shaped to a width of 10 mm with a razor, whereby a patterned cured product with a width of 10 mm was obtained.

In each of Examples 2, 3, 5 and 6, and Comparative Example 1, the resulting resin film was exposed in a broad band (BB) at an amount of exposure of 600 mJ/cm², with Mask Aligner MA-8 (manufactured by SUSS MicroTec SE), and then cured with a vertical diffusion furnace μ-TF under a nitrogen atmosphere at a curing temperature for a curing time as described in Table 1, and thus a cured product having a thickness of 10 μm was obtained. The cured product was immersed in an aqueous 4.9% by mass hydrofluoric acid solution, and thus the cured product was released from the Si substrate. The cured product obtained was shaped to a width of 10 mm with a razor, whereby a patterned cured product with a width of 10 mm was obtained.

A TMA tester (TMA2940 manufactured by Du Pont) was used, and the linear thermal expansion coefficient from 30° C. to 100° C. in a planar direction of a patterned cured product as a measurement sample was measured under conditions of an initial sample length of 10 mm, a load of 10 g, and a rate of temperature rise of 5° C./min. The results obtained are each shown as the thermal expansion coefficient in Table 1.

### (Possibility of Insulation Film Lamination)

A resin film was formed by spin-coating an 8-inch Si wafer with the insulation film forming material in each of Examples 1 to 6 and Comparative Example 1, by a spin coater as an application apparatus, and heating and drying the resultant at 95° C. for 120 seconds and then at 105° C. for 120 seconds.

In each of Examples 2, 3, 5 and 6, and Comparative Example 1, the resin film obtained was irradiated with light at a wavelength of 365 nm at an amount of exposure of 600 mJ/cm², and thus a resin film exposed was obtained.

The resulting resin film exposed and the resin film in each of Examples 1 and 4 were each cured with a vertical diffusion furnace μ-TF under a nitrogen atmosphere at a curing temperature for a curing time as described in Table 1, and thus a cured film was obtained.

The cured film in each of Examples 1 to 6, among such cured films obtained, was polished by a CMP method, and thus a cured film polished was obtained. The cured film in Comparative Example 1, among such cured films obtained, was not polished. Such each cured film was subjected to scrub cleaning with a common detergent, and thereafter a part of the cured film cleaned was singulated to a 5-mm square by a blade dicer (DISCO DFD-6362), whereby a resin-attached chip was obtained. The resin-attached chip obtained was pressure-bonded to the remaining cured film not singulated, by a flip chip bonder (MD4000 manufactured by TORAY ENGINEERING Co., Ltd.) at a predetermined pressure and a joining temperature shown in Table 1 for 15 seconds, and thus a chip-attached cured film was produced. Five such chips each pressure-bonded to the cured film, with respect to each of the insulation film forming materials, were evaluated as described below.

The cured film was subjected to measurement of the surface roughness Ra within 10 μm², with an AFM (atomic force microscope). A case in which the surface roughness Ra was 2.0 nm or less was rated as A, and a case in which the surface roughness Ra exceeded 2.0 nm was rated as B. The results obtained are shown in Table 1.

### (Evaluation)

The resulting chip-attached cured film was observed about adhesion failure between resin interfaces with SAT (ultrasonic penetrant inspection: Scanning Acoustic Tomography). Evaluation criteria of the adhesion failure are described below. The results are shown in

### Table 1.

### —Evaluation Criteria of Lamination Failure—

A: lamination failure was observed in 10 chips or less among 50 chips.
B: lamination failure was observed in more than 10 chips among 50 chips.

### (Possibility of Joining Between Copper Electrodes)

A pair of upper and lower 12-inch wafers each having Cu wiring for testing joining conduction, on a Si wafer having a SiO₂ layer at a thickness of 500 nm from the surface formed by thermal oxidization processing, was prepared, and this was adopted as a 12-inch Cu-patterned wafer. The 12-inch Cu-patterned wafer had wiring having a height of 2 μm, and a Cu pillar for joining, having a diameter of about 10 μm and a height of 5 μm, on a joining portion thereon.

A Cu-patterned resin film was formed by spin-coating a 12-inch Cu-patterned wafer with the insulation film forming material in each of Examples 1 to 6 and Comparative Example 1, by a spin coater as an application apparatus, so that the thickness of the resin film after curing was about 11 μm, and heating and drying the resultant at 95° C. for 120 seconds and then at 105° C. for 120 seconds. In each of Examples 2, 3, 5 and 6, and Comparative Example 1, the resin film obtained was irradiated with light at a wavelength of 365 nm at an amount of exposure of 600 mJ/cm².

The resulting Cu-patterned resin film was cured with a vertical diffusion furnace μ-TF under a nitrogen atmosphere at a curing temperature for a curing time as described in Table 1, and thus a Cu-patterned cured film was obtained. The Cu-patterned cured film in each of Examples 1 to 6, among such Cu-patterned cured films obtained, was polished by a CMP method until reveal of the Cu pillar, and thus a Cu-patterned cured film polished was obtained. The resulting Cu-patterned cured film polished was subjected to measurement of the surface roughness Ra within 10 μm², with an AFM (atomic force microscope), and the Ra on each of a resin and a Cu electrode was confirmed to be 2.0 nm or less.

The height of the cured film (organic insulation film) on the Cu-patterned cured film polished was higher than the electrode height combined of the wiring and the Cu pillar, by 5 nm.

The difference between the height of the cured film (organic insulation film) and the electrode height combined of the wiring and the Cu pillar was defined as the arithmetic average value in measurement at five points in the Cu-patterned cured film polished, with an atomic force microscope (AFM).

The Cu-patterned cured film polished was subjected to scrub cleaning with a common detergent, and thereafter a part of the cured film cleaned was singulated to a 5-mm square by a blade dicer (DISCO DFD-6362), whereby a Cu-patterned resin chip was obtained. The Cu-patterned cured film not singulated and the Cu-patterned resin chip were immersed in a predetermined organic acid for 30 seconds, to remove an oxidized layer on each copper surface, and thereafter dried on a hot plate at 85° C. for 3 minutes. After the drying, the Cu-patterned resin chip was pressure-bonded to the Cu-patterned cured film at a predetermined pressure and a joining temperature shown in Table 1 for 15 seconds, and thus a chip-attached Cu-patterned wafer was produced. Thereafter, the chip-attached Cu-patterned wafer was heat-treated under a nitrogen atmosphere at 230° C. for 30 minutes.

The chip-attached Cu-patterned wafer produced was subjected to electrical resistance measurement with a standard probe tester. A wiring pattern passing through 20 pairs of joining portions was used in the electrical resistance measurement. In Comparative Example 1, no joining between copper electrodes could be made due to lamination failure caused between insulation films, and therefore possibility of joining between copper electrodes was not evaluated.

### —Criteria of Evaluation of Joining Between Copper Electrodes—

A: an electrical resistance of 2000Ω or less
B: an electrical resistance of more than 2000Ω

TABLE 1

| | | | | | | | Comparative |
|---|---|---|---|---|---|---|---|
| | Example 1 | Example 2 | Example 3 | Example 4 | Example 5 | Example 6 | Example 1 |
| Polyimide Precursor A1 | 100 | 80 | 80 | | | | |
| Polyimide Precursor A2 | | 20 | | | | | 100 |
| Polyimide Precursor A3 | | | 20 | | 100 | | |
| Polyimide Precursor A4 | | | | 100 | | | |
| Polyimide Precursor A5 | | | | | | 50 | |
| Polyimide Precursor A6 | | | | | | 50 | |
| Solvent B1 | 150 | 150 | 150 | 150 | 150 | | 150 |
| Solvent B2 | | | | | | 110 | |
| Solvent B3 | | | | | | 30 | |
| Polymerizable monomer C1 | 5 | 5 | 5 | 5 | | 15 | 15 |
| Polymerizable monomer C2 | 5 | 5 | 5 | | 20 | | |
| Rust inhibitor D1 | 1.5 | 1.5 | 1.5 | 1.5 | 1.5 | 1.5 | 1.5 |
| Polymerization initiator E1 | | 10 | 10 | | 10 | 10 | 10 |
| Polymerization initiator E2 | | 1 | 1 | | 1 | 1 | 1 |
| Polymerization initiator E3 | 2 | 2 | 2 | 2 | 2 | 2 | |
| Antioxidant F1 | 5 | | | 5 | | | |
| Adhesion aid G1 | 3 | 3 | 3 | 3 | 3 | 3 | 8 |
| Curing Temperature (° C.) | 250 | 250 | 250 | 250 | 250 | 250 | 350 |
| Curing Time (hours) | 2 | 2 | 2 | 2 | 2 | 2 | 2 |
| Thermal Expansion | 15 | 20 | 25 | 20 | 70 | 60 | 60 |
| Coefficient (ppm/K) | | | | | | | |
| Chemical Mechanical | With | With | With | With | With | With | Without |
| Polishing | polishing | polishing | polishing | polishing | polishing | polishing | polishing |
| Surface Roughness Ra | A | A | A | A | A | A | B |
| Joining Temperature (° C.) | 25 | 25 | 25 | 25 | 25 | 25 | 250 |
| Possibility of Lamination | A | A | A | A | A | A | B |
| Possibility of Joining Between | A | A | A | A | B | B | — |
| Copper Electrodes | | | | | | | |

As shown in Table 1, insulation film lamination was possible at 25° C. in Examples 1 to 6, whereas lamination failure was caused regardless of insulation film lamination at 250° C. in Comparative Example 1.

The disclosure of Japanese Patent Application No. 2022-063656 filed on Apr. 6, 2022, is hereby incorporated by reference in its entirety.

All the documents, patent applications and technical standards that are described in the present specification are hereby incorporated by reference to the same extent as if each individual document, patent application or technical standard is concretely and individually described to be incorporated by reference.

### REFERENCE SIGNS LIST

1, 1a, 401: semiconductor device
10: first semiconductor chip
20: second semiconductor chip
30: pillar section
40: rewiring layer
50: substrate
60: circuit substrate
61: terminal electrode
100: first silicon substrate
101: first silicon substrate body
101a: one surface
102: insulation film (first insulation film)
103: terminal electrode (first electrode)
103a: surface
200: second silicon substrate
201: second silicon substrate body
201a: one surface
202: insulation film (second insulation film)
203: terminal electrode (second electrode)
203a: surface
205: semiconductor chip
300: pillar
301: resin
410: semiconductor wafer (first semiconductor substrate)
411: substrate body (first semiconductor substrate body)
412: insulation film (first insulation film)
413: terminal electrode (first electrode)
420: semiconductor chip (second semiconductor substrate)
421: substrate body
422: insulation film portion (second insulation film)
423: terminal electrode (second electrode)
A: cutting line
H: heat
M1 to M3: semi-product
S1: insulation joining portion
S2: electrode joining portion
S3: insulation joining portion
S4: electrode joining portion

1. A method of manufacturing a semiconductor device, the method comprising:
preparing a first semiconductor substrate comprising a first semiconductor substrate body, a first electrode, and a first organic insulation film having a surface roughness Ra of 2.0 nm or less, the first electrode and the first organic insulation film being provided on one surface of the first semiconductor substrate body;
preparing a second semiconductor substrate comprising a second semiconductor substrate body, a second electrode, and a second organic insulation film having a surface roughness Ra of 2.0 nm or less, the second electrode and the second organic insulation film being provided on one surface of the second semiconductor substrate body;
performing lamination of the first organic insulation film and the second organic insulation film at 70° C. or less; and
performing joining of the first electrode and the second electrode.

2. The method of manufacturing a semiconductor device according to claim 1, wherein each of thermal expansion coefficients of the first organic insulation film and the second organic insulation film is 50 ppm/K or less.

3. The method of manufacturing a semiconductor device according to claim 1, wherein each of the first organic insulation film and the second organic insulation film is a polyimide film, a polybenzoxazole film, a benzocyclobutene film, a polyamide imide film, an epoxy resin film, an acrylic resin film, or a methacrylic resin film.

4. The method of manufacturing a semiconductor device according to claim 1, wherein the first semiconductor substrate is a semiconductor wafer, and the second semiconductor substrate is a semiconductor wafer.

5. The method of manufacturing a semiconductor device according to claim 1, wherein the first semiconductor substrate is a semiconductor wafer, and the second semiconductor substrate is a semiconductor chip.

6. The method of manufacturing a semiconductor device according to claim 1, wherein the first semiconductor substrate is a semiconductor chip, and the second semiconductor substrate is a semiconductor chip.

7. The method of manufacturing a semiconductor device according to claim 1, wherein a total thickness of an organic insulation film formed by lamination of the first organic insulation film and the second organic insulation film, in the manufactured semiconductor device, is 0.1 μm or more.

8. The method of manufacturing a semiconductor device according to claim 1, wherein at least one of the one surface of the first semiconductor substrate or the one surface of the second semiconductor substrate is polished before lamination of the first organic insulation film and the second organic insulation film is carried out.

9. The method of manufacturing a semiconductor device according to claim 8, wherein the polishing comprises chemical mechanical polishing.

10. The method of manufacturing a semiconductor device according to claim 9, wherein the polishing further comprises mechanical polishing.

11. The method of manufacturing a semiconductor device according to claim 1, wherein a height of the first organic insulation film is equal to or higher than a height of the first electrode, and a height of the second organic insulation film is equal to or higher than a height of the second electrode.

12. The method of manufacturing a semiconductor device according to claim 11, wherein the height of the first organic insulation film is higher than the height of the first electrode by 0.1 nm or more, and the height of the second organic insulation film is higher than the height of the second electrode by 0.1 nm or more.

13. A hybrid bonding insulation film forming material comprising a thermosetting polyamide and a solvent, wherein a thermal expansion coefficient of a cured product of the hybrid bonding insulation film forming material is 50 ppm/K or less.

14. The hybrid bonding insulation film forming material according to claim 13, wherein the thermosetting polyamide comprises a polybenzoxazole precursor or a polyimide precursor.

15. The hybrid bonding insulation film forming material according to claim 13, wherein the thermosetting polyamide comprises a polyimide precursor, and the hybrid bonding insulation film forming material further comprises a polyimide resin.

16. A semiconductor device comprising:
a first semiconductor substrate comprising a first semiconductor substrate body, a first organic insulation film, and a first electrode, the first organic insulation film and the first electrode being provided on one surface of the first semiconductor substrate body; and
a second semiconductor substrate comprising a second semiconductor substrate body, a second organic insulation film, and a second electrode, the second organic insulation film and the second electrode being provided on one surface of the second semiconductor substrate body, wherein:
the first organic insulation film and the second organic insulation film are joined, and the first electrode and the second electrode are joined, and
each of thermal expansion coefficients of the first organic insulation film and the second organic insulation film is 50 ppm/K or less.
